(19) United States
(12) Patent Application Publication
(10) Pub. No.: US 2024/0019492 A1
(43) Pub. Date: Jan. 18, 2024

(54) COMPUTER-READABLE RECORDING MEDIUM STORING TEST PATTERN GENERATION PROGRAM, TEST PATTERN GENERATION APPARATUS, AND TEST PATTERN GENERATION METHOD

(71) Applicant: Fujitsu Limited, Kawasaki-shi (JP)

(72) Inventor: Daisuke MARUYAMA, Kawasaki (JP)

(73) Assignee: Fujitsu Limited, Kawasaki-shi (JP)

(21) Appl. No.: 18/191,094

(22) Filed: Mar. 28, 2023

(30) Foreign Application Priority Data
Jul. 13, 2022 (JP) 2022-112415

(51) Int. Cl. G01R 31/3185; G01R 31/317

(52) U.S. Cl. CPC G01R 31/318525; G01R 31/31726

(57) ABSTRACT

A non-transitory computer-readable recording medium stores a test pattern generation program for causing a computer to execute processing including: detecting, based on design information of a semiconductor integrated circuit, a plurality of clock domains each of which operates according to any one of a plurality of clock signals; changing application order of the plurality of clock signals when a test pattern that includes the application order and a first input value to a first object circuit is generated, based on which of the plurality of clock domains a first holding circuit that sends the first input value or a first response value from the first object circuit to the first circuit region and a second holding circuit that receives the first response value from the first circuit region, belong to; and outputting information regarding the test pattern.

### CROSS-REFERENCE TO RELATED APPLICATION

This application is based upon and claims the benefit of priority of the prior Japanese Patent Application No. 2022-112415, filed on Jul. 13, 2022, the entire contents of which are incorporated herein by reference.

### FIELD

The embodiments discussed herein are related to a test pattern generation program, a test pattern generation apparatus, and a test pattern generation method.

### BACKGROUND

In tests of semiconductor integrated circuits, test patterns are generated and circuit responses are observed to detect faults assumed in the semiconductor integrated circuits by using test circuits including a plurality of serially coupled scan flip-flops (hereinafter referred to as scan FFs). A path including the plurality of serially coupled scan FFs is also called a scan chain.

Japanese Laid-open Patent Publication No. 2016-109427 and Japanese Laid-open Patent Publication No. 2019-46087 are disclosed as related art.

### SUMMARY

According to an aspect of the embodiments, a non-transitory computer-readable recording medium stores a test pattern generation program for causing a computer to execute processing including: detecting, based on design information of a semiconductor integrated circuit, a plurality of clock domains each of which operates according to any one of a plurality of clock signals; changing application order of the plurality of clock signals when a test pattern that includes the application order and a first input value to a first object circuit is generated, based on which of the plurality of clock domains a first holding circuit that sends the first input value or a first response value from the first object circuit to the first circuit region and a second holding circuit that receives the first response value from the first circuit region, belong to; and outputting information regarding the test pattern.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a test pattern generation method and a test pattern generation apparatus of a first embodiment;

FIG. 2 is a diagram illustrating an example of a crossing portion in a large scale integrated circuit (LSI);

FIG. 3 is a diagram illustrating an example of generation of a test pattern in a single clock application method;

FIG. 4 is a diagram illustrating an example of generation of a test pattern in a multiple clock application method (time expansion method);

FIG. 5 is a diagram illustrating an example of generation of a test pattern in a multiple clock application method (clock application order fixing method);

FIG. 6 is a diagram illustrating the number of clock signals and combinations of crossings for which additional test patterns are generated;

FIG. 7 is a diagram for describing a problem of the method (c) for a circuit including a non-scan flip-flop (FF);

FIG. 8 is a diagram illustrating an example of generation of a test pattern in the test pattern generation method of the present embodiment;

FIG. 9 is a diagram illustrating an example of generation of a test pattern by a dynamic fault compression method;

FIG. 10 is a diagram illustrating an example of a clock unify, clock supply/stop method;

FIG. 11 is a block diagram illustrating a hardware example of the test pattern generation apparatus;

FIG. 12 is a block diagram illustrating a functional example of the test pattern generation apparatus;

FIG. 13 is a flowchart illustrating an example of a procedure of generating a test pattern for a static test;

FIG. 14 is a flowchart illustrating an example of a procedure of detecting clock domains;

FIG. 15 is a diagram illustrating an example of detecting clock domains;

FIG. 16 is a flowchart illustrating an example of a procedure of generating a test pattern;

FIG. 17 is a flowchart illustrating an example of a procedure of gate processing;

FIG. 18 is a diagram illustrating a detailed example of clock application order information;

FIG. 19 is a diagram illustrating an example of updating the clock application order information using a decision tree;

FIG. 20 is a diagram illustrating an outline of a high-speed test;

FIG. 21 is a diagram illustrating an example of time expansion during the high-speed test;

FIG. 22 is a diagram illustrating an example of a time frame reuse method;

FIG. 23 is a flowchart illustrating an example of a procedure of generating a test pattern for the high-speed test;

FIG. 24 is a flowchart illustrating an example of a procedure of clock switch processing;

FIG. 25 is a flowchart illustrating an example of a procedure of clock switch preparation processing;

FIG. 26 is a flowchart illustrating an example of a procedure of circuit state acquisition processing;

FIG. 27 is a diagram illustrating an example of circuit state acquisition and setting processing (part 1); and

FIG. 28 is a diagram illustrating an example of the circuit state acquisition and setting processing (part 2).

### DESCRIPTION OF EMBODIMENTS

A test using the scan FFs (scan test) is performed in operation order of scan-in operation, capture operation, and scan-out operation. In the scan-in operation, an input value to an object circuit is set in each scan FF. In the capture operation, an input value set in a scan FF on a sending side is sent to the object circuit, and a response value from the object circuit is captured by a scan FF on a receiving side in synchronization with a clock signal. In the scan-out operation, the value held in each scan FF is read and compared with an expected value to determine presence or absence of a fault.

A test pattern in a semiconductor integrated circuit using a plurality of clock signals includes a combination of values of 0 or 1 set to each scan FF and application order of each clock signal. For such a semiconductor integrated circuit, a test pattern is generated in consideration of a portion across circuit regions (hereinafter referred to as clock domains) that operate with different clock signals (crossing portion between different clock domains). This is because, in a case where the application order of the clock signals to the clock domains on the sending side and the receiving side for the crossing portion is set so that the receiving side is a later order, the setting value of the scan FF on the sending side is updated (disabled) before contents of a fault in the crossing portion are updated in the scan FF on the receiving side. Conversely, in a case where the application order of the clock signals to the clock domains on the sending side and the receiving side is set so that the sending side is a later order, the setting value of the scan FF on the sending side is updated after the contents of the fault in the crossing portion are updated by the scan FF on the receiving side.

As a method of generating a test pattern for the semiconductor integrated circuit including the crossing portion as described above, there are, for example, the following methods.

(a) Single Clock Application Method

This method is a method of generating a test pattern to which one clock signal is applied between the scan-in operation and the scan-out operation. In this method, since there is one time frame that expresses a circuit state of one test pattern, and there is no update of a state of a scan FF due to application of a different clock signal in that test pattern, it is not needed to consider the crossing portion as described above.

(b) Multiple Clock Application Method (Time Expansion Method)

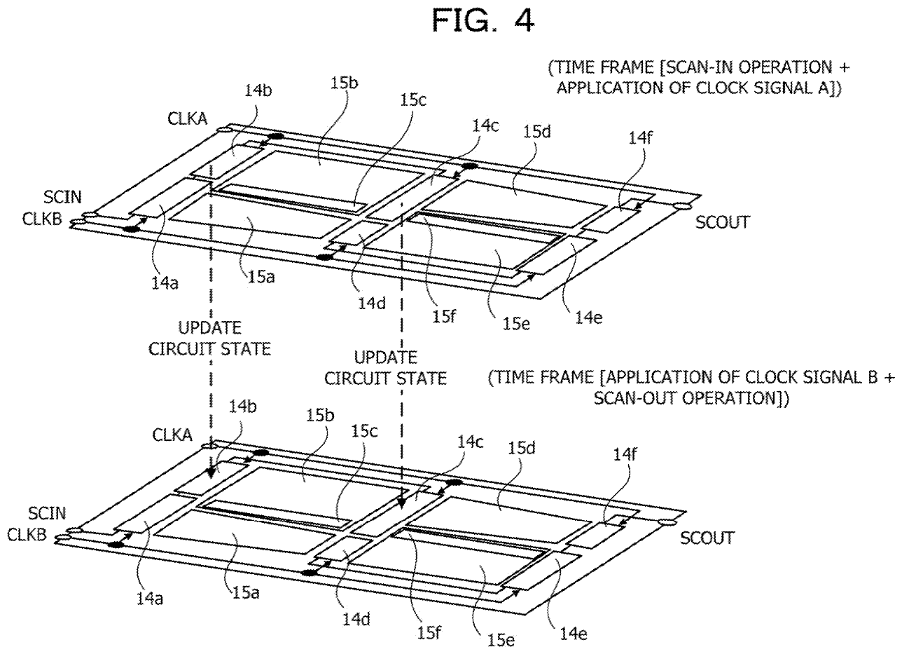

This method is a method of generating a test pattern to which a plurality of clock signals is applied between the scan-in operation and the scan-out operation. In this method, since time frames equal to the number of clock signals to be applied (circuit information for each clock application time) are used, it is possible to express update of a state of a scan FF by application of the clock signals. With this configuration, it is possible to generate an appropriate test pattern for the semiconductor integrated circuit including the crossing portion. Note that examples of the time frame and time expansion will be described later (see FIG. 4).

(c) Multiple Clock Application Method (Clock Application Order Fixing Method)

This method is also a method of generating a test pattern to which a plurality of clock signals is applied between the scan-in operation and the scan-out operation, as in the method (b). However, in this method, unlike the method (b), it is possible to use one time frame for one test pattern by devising recognition of the crossing portion and decision of the application order of the clock signals. In this method, since the setting value of the scan FF on the sending side is not disabled by setting the application order of the clock signals on the sending side and the receiving side to the crossing portion so that the receiving side is a former order, as described above, the application order of the clock signals is decided based on the number of faults in each crossing portion. At this time, a crossing portion where the setting value of the scan FF is disabled is temporarily excluded from the test, so that a useless test pattern is not generated.

(d) Clock Unify, Clock Supply/Stop Method

In the methods (a) to (c) described above, the plurality of clock signals supplied to each clock domain in the scan test is independent. However, in the present method, a supply source of scan clock signals to each clock domain is unified. Additionally, supply or stop is controlled for each scan clock signal supplied to each clock domain. Furthermore, in this method, timing analysis is used to ensure that the circuit operates normally even when the scan clock signals are simultaneously applied to each clock domain.

In the existing methods as described above, there is a problem that, when the number of clock signals increases, test costs (time, resources, and the like) increase and test quality deteriorates. Note that the reason why the test costs increase and the test quality deteriorates in the methods (a) to (d) described above will be described later.

In one aspect, an object of an embodiment is to reduce test costs of a semiconductor integrated circuit using a plurality of clock signals.

Hereinafter, modes for carrying out embodiments will be described with reference to the drawings.

### First Embodiment

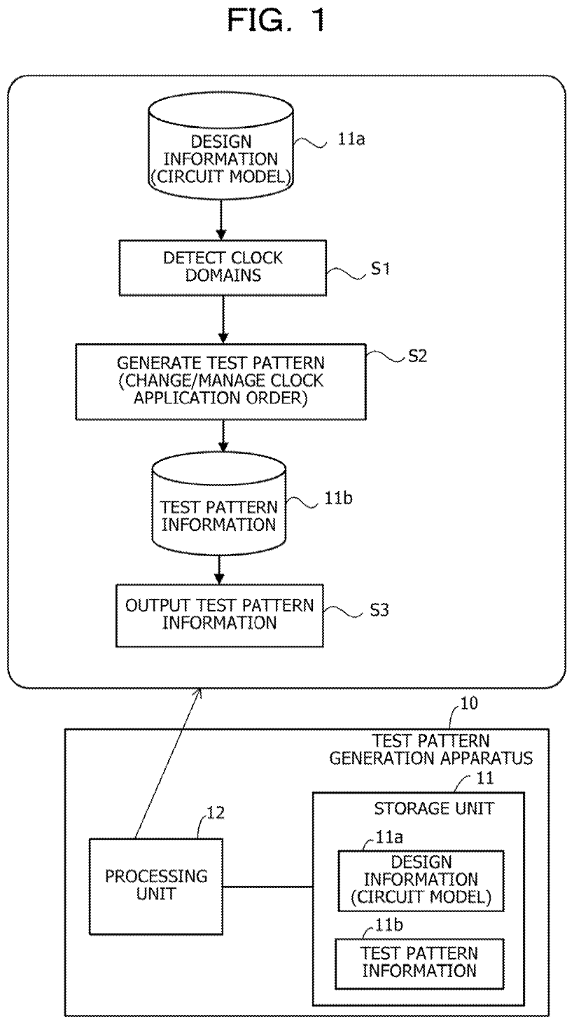

FIG. 1 is a diagram illustrating an example of a test pattern generation method and a test pattern generation apparatus of a first embodiment.

A test pattern generation apparatus 10 of the first embodiment generates a test pattern for performing a test of a semiconductor integrated circuit (hereinafter referred to as a large scale integrated circuit (LSI)), and performs the test (fault simulation) by using the generated test pattern.

The test pattern generation apparatus 10 includes a storage unit 11 and a processing unit 12.

The storage unit 11 is a volatile storage device such as a random access memory (RAM) or a non-volatile storage device such as a hard disk drive (HDD) or a flash memory.

The storage unit 11 stores design information (circuit model) 11a of the LSI, generated test pattern information 11b, and the like. Note that the design information may include a fault to be detected and various types of test information.

Note that the test pattern generation apparatus 10 may receive input from a user and create the design information 11a or the like based on the input, or the test pattern generation apparatus 10 may acquire the design information 11a from another device.

The processing unit 12 may be implemented by a processor that is hardware such as a central processing unit (CPU) or a digital signal processor (DSP). Note that the processing unit 12 may include an electronic circuit such as an application specific integrated circuit (ASIC) or a field programmable gate array (FPGA). The processor executes a program stored in a memory such as a RAM. For example, a test pattern generation program is executed. Note that a set of a plurality of processors may be referred to as “multiprocessor” or simply as “processor”.

The processing unit 12 generates a test pattern in consideration of a portion across clock domains that operate with different clock signals (crossing portion between different clock domains).

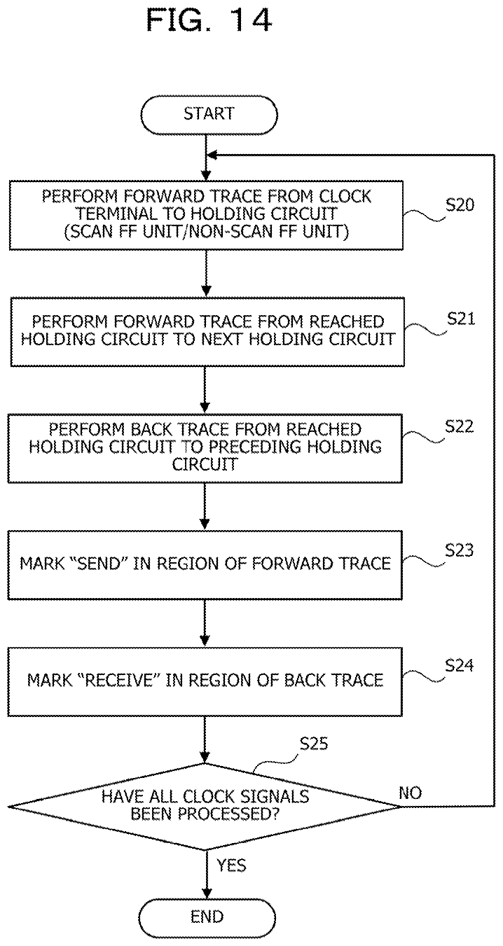

First, based on the design information 11a stored in the storage unit 11, the processing unit 12 detects a plurality of clock domains each operating according to any one of a plurality of clock signals (Step S1). A specific procedure of detecting the clock domains will be described later (see FIG. 14). Note that the plurality of clock signals is, for example, a plurality of clock signals having different frequencies (or phases) from each other, a plurality of clock signals having the same frequency (or phase) but whose application is controlled separately, or the like.

After the processing of Step S1, the processing unit 12 generates a test pattern (Step S2). The test pattern includes an input value (also called a scan-in value) to the object circuit and application order of the plurality of clock signals. The input value is represented by a combination of values of 0 or 1 set in a holding circuit such as a scan flip-flop (FF). The input value is generated by, for example, an automatic test pattern generator (ATPG) function executed by the processing unit 12 so that an object fault (for example, a stuck-at fault or the like) may be detected. Provisional application order of the plurality of clock signals (application order before changing the application order by processing of the present embodiment) may also be decided by the ATPG function.

Here, the processing unit 12 changes the application order based on which of the plurality of clock domains a first holding circuit that sends the input value to the object circuit or a response value from the object circuit to a circuit region of the LSI and a second holding circuit that receives the response value from the circuit region of the LSI are belong to any one of the plurality of clock domains. The response value is output of the object circuit that operates based on the input value, and in a case where a fault occurs, the value reflects the fault. Furthermore, the processing unit 12 manages the application order.

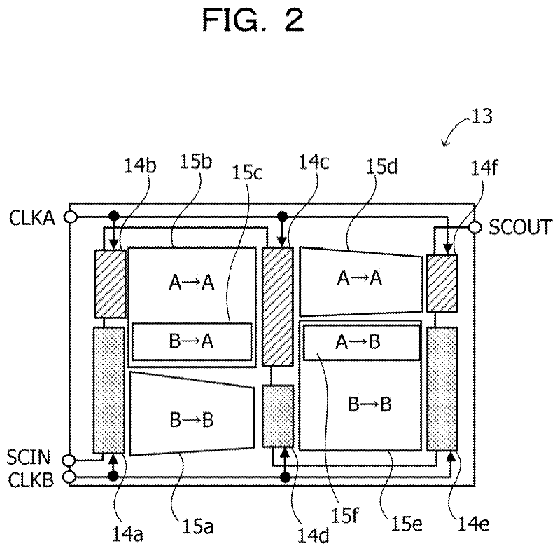

FIG. 2 is a diagram illustrating an example of the crossing portion in the LSI.

An LSI 13 includes scan FF units 14a, 14b, 14c, 14d, 14e, and 14f serially coupled between a scan-in terminal SCIN and a scan-out terminal SCOUT. Each of the scan FF units 14a to 14f includes one or a plurality of serially coupled scan FFs. A value of 0 or 1 included in an input value from the scan-in terminal SCIN is set to each scan FF during scan-in operation.

Here, among the scan FF units 14a to 14f, the scan FF units 14b, 14c, and 14f operate according to a clock signal A applied to a clock terminal CLKA. Among the scan FF units 14a to 14f, the scan FF units 14a, 14d, and 14e operate according to a clock signal B applied to a clock terminal CLKB. For example, the scan FF units 14a, 14d, and 14e and the scan FF units 14b, 14c, and 14f belong to different clock domains.

Moreover, the LSI 13 includes regions 15a, 15b, 15c, 15d, 15e, and 15f. The regions 15a to 15f are, for example, circuit regions of combinational circuits of various gate circuits. Any one or all of the regions 15a to 15f include the object circuit described above.

In the example of FIG. 2, the scan FF unit 14a sends input values to the regions 15a and 15c. The scan FF unit 14b sends an input value to the region 15b. The scan FF unit 14c sends input values to the regions 15d and 15f and receives response values from the regions 15b and 15c. The scan FF unit 14d sends an input value to the region 15e and receives a response value from the region 15a. The scan FF unit 14e receives response values from the regions 15e and 15f, and the scan FF unit 14f receives a response value from the region 15d.

Thus, the scan FF unit 14a corresponds to the first holding circuit described above for the region 15b, and the scan FF unit 14b corresponds to the first holding circuit described above for the regions 15a and 15c. Furthermore, the scan FF unit 14c corresponds to the first holding circuit described above for the regions 15d and 15f, and corresponds to the second holding circuit described above for the regions 15b and 15c. The scan FF unit 14d corresponds to the first holding circuit described above for the region 15e, and corresponds to the second holding circuit described above for the region 15a. The scan FF unit 14e corresponds to the second holding circuit described above for the regions 15e and 15f, and the scan FF unit 14f corresponds to the second holding circuit described above for the region 15d.

Note that “A→A”, “A→B”, or the like displayed in each of the regions 15a to 15f represents a clock domain to which the first holding circuit that sends an input value to the object circuit to each region belongs and a clock domain to which the second holding circuit that receives output from each region belongs. “A” represents a clock domain that operates according to the clock signal A, and “B” represents a clock domain that operates according to the clock signal B.

In FIG. 2, the region 15c displayed as “B→A” and the region 15f displayed as “A→B” correspond to the crossing portions described above.

As described above, in a case where the application order of the clock signals to clock domains on a sending side and a receiving side for the crossing portion is set so that the receiving side is a later order, the setting value of the first holding circuit on the sending side is updated before contents of a fault in the crossing portion are updated in the second holding circuit on the receiving side.

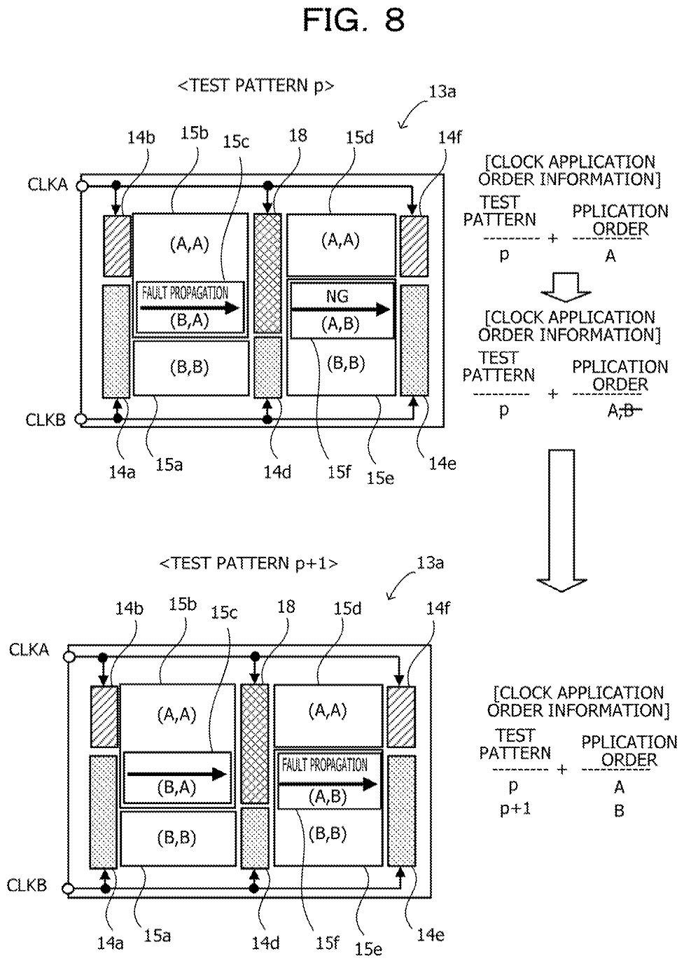

Thus, for example, in a case where the region 15f displayed as “A→B” is used as a path that propagates a response value from a test object or the object circuit, and the application order is provisionally decided in the order of the clock signals A and B, the processing unit 12 changes the application order so as to avoid such application order. A specific example of changing the application order will be described later (see FIG. 8).

The processing unit 12 outputs information regarding the generated test pattern (test pattern information 11b) (Step S3). For example, the processing unit 12 may output the test pattern information 11b to the storage unit 11 for storage, or may output the test pattern information 11b to the outside of the test pattern generation apparatus 10.

The test pattern information 11b output in this way is used to, for example, confirm presence or absence of a fault in an actual test before shipment of the LSI, and the like.

According to the test pattern generation apparatus 10 as described above, since generation of a useless test pattern may be prevented, test costs may be reduced. Hereinafter, effects of the test pattern generation apparatus 10 of the present embodiment compared with the methods (a) to (d) of generating a test pattern described above will be described.

Comparison with (a) Single Clock Application Method

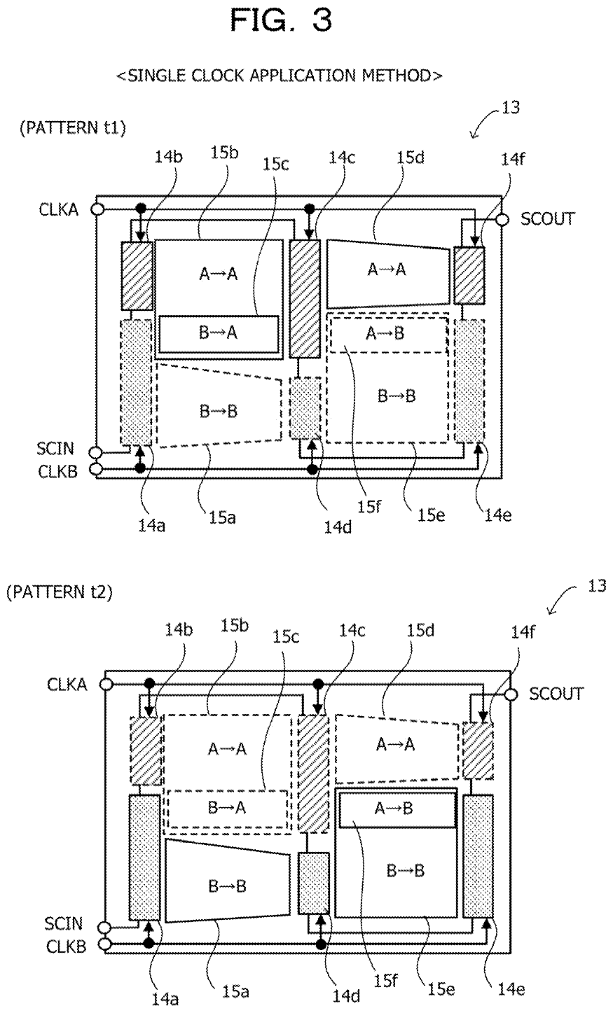

FIG. 3 is a diagram illustrating an example of generation of a test pattern in the single clock application method. In FIG. 3, the LSI 13 described above (see FIG. 2) is indicated. Note that the scan FFs and the regions that do not operate are indicated by broken lines.

A pattern t1 is a test pattern to which the clock signal A is applied. A pattern t2 is a test pattern to which the clock signal B is applied.

In the single clock application method, since the number of clock signals applied between the scan-in operation and the scan-out operation is limited to one, a range of the circuit to be tested is also limited. Thus, as the number of clock signals increases, the number of test patterns used for performing a test of the entire circuit also increases, and the numbers of times of the scan-in operation and the scan-out operation also increase, resulting in an increase in the test costs.

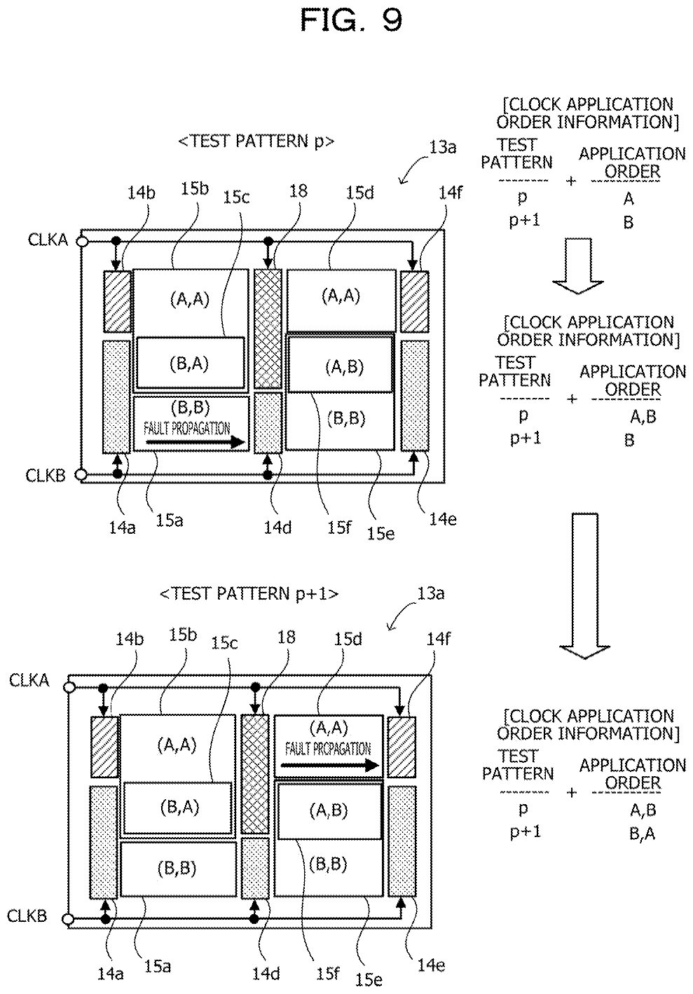

Compared to this method, in the test pattern generation method of the present embodiment, the number of clock signals to be applied between the scan-in operation and the scan-out operation is not limited to one. As will be described later, it is possible to apply a plurality of clock signals between the scan-in operation and the scan-out operation (see FIG. 9). Thus, the increase in the test costs may be suppressed.

Comparison with (b) Multiple Clock Application Method (Time Expansion Method)

In this method, time frames equal to the number of clock signals to be applied between the scan-in operation and the scan-out operation are used, and as the number of clock signals increases, the number of time frames to be expanded also increases. Additionally, the increase in the number of time frames means an increase in the number of search spaces in which fault detection conditions are searched, which means that a search problem to be handled becomes more complex.

FIG. 4 is a diagram illustrating an example of generation of a test pattern in the multiple clock application method (time expansion method). In FIG. 4, the LSI 13 described above (see FIG. 2) is indicated, in which a time frame in which the scan-in operation and application of the clock signal A are performed and a time frame in which application of the clock signal B and the scan-out operation are performed are indicated.

In FIG. 4, detecting a fault that occurs in the region 15f is considered. In this case, the search for the fault detection conditions is performed not only in the time frame [the application of the clock signal B+the scan-out operation] in which observation is performed, but also in the time frame [the scan-in operation+the application of the clock signal A] in which an input value to the object circuit is set. Additionally, moreover, the search in the time frame [the application of the clock signal B+the scan-out operation] is performed in consideration of update of the circuit state by the clock signal A.

As the search problem becomes more complex in this way, a search time becomes longer and a test pattern generation time increases.

Usually, in the actual generation of a test pattern, search termination criteria are set in order to avoid infinite (long) search time. Thus, as the search problem to be handled becomes more complex, a possibility of not being able to generate a test pattern capable of detecting a fault increases due to the search termination. For example, in this method, with the increase in the number of clock signals, there is also a problem of deterioration in test quality in which a fault detection rate decreases due to failure in generation of a test pattern.

Compared to this method, in the test pattern generation method of the present embodiment, since one time frame is used between the scan-in operation and the scan-out operation, it is possible to avoid complication of the search problem and to suppress the increase in the test costs and the deterioration in the test quality due to the search termination.

Comparison with (c) Multiple Clock Application Method (Clock Application Order Fixing Method)

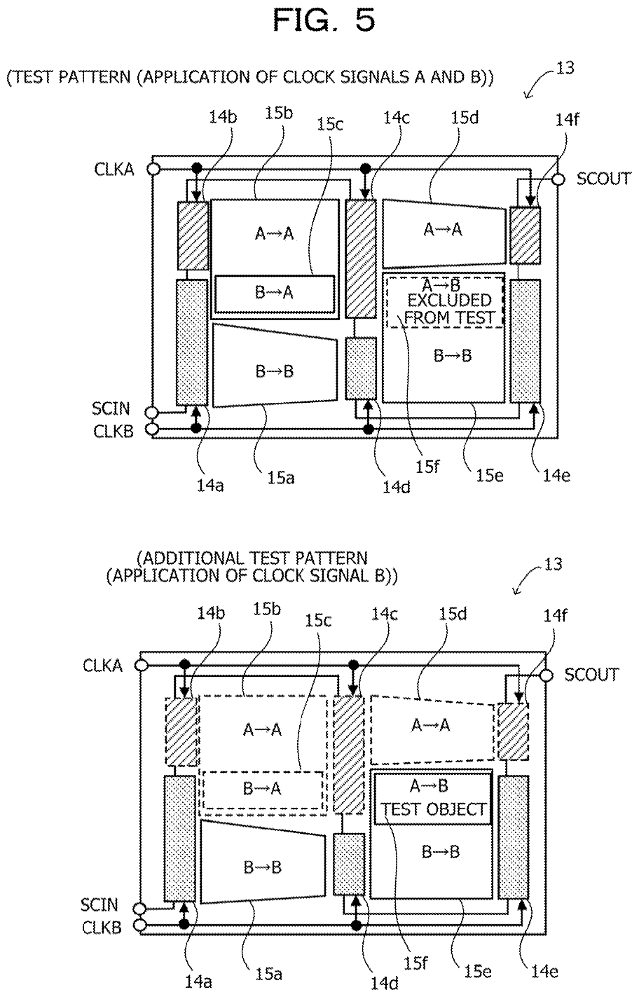

FIG. 5 is a diagram illustrating an example of generation of a test pattern in the multiple clock application method (clock application order fixing method). In FIG. 5, the LSI 13 described above (see FIG. 2) is indicated.

In the example of FIG. 5, a test pattern with the application order of the clock signal A and the clock signal B is generated. In this test pattern, a test of the region 15c as the crossing portion may be performed, but the region 15f as the crossing portion in which an input value of the scan FF unit 14c is disabled is temporarily excluded from the test.

Then, an additional test pattern to which only the clock signal B is applied is generated, the crossing portion of the region 15f is returned to the test object, and the test is performed. Each time the number of additional test patterns increases, the numbers of times of the scan-in operation and the scan-out operation also increase, thus increasing the test costs. Hereinafter, “A→B”, “B→A”, or the like represented by a combination of reference signs of two different clock signals applied to the clock domains on the sending side and the receiving side is referred to as a combination of crossings.

In this method, since the order of the clock signals to be applied is fixed first, as the number of clock signals increases, the number of combinations of crossings for which additional test patterns are generated increases.

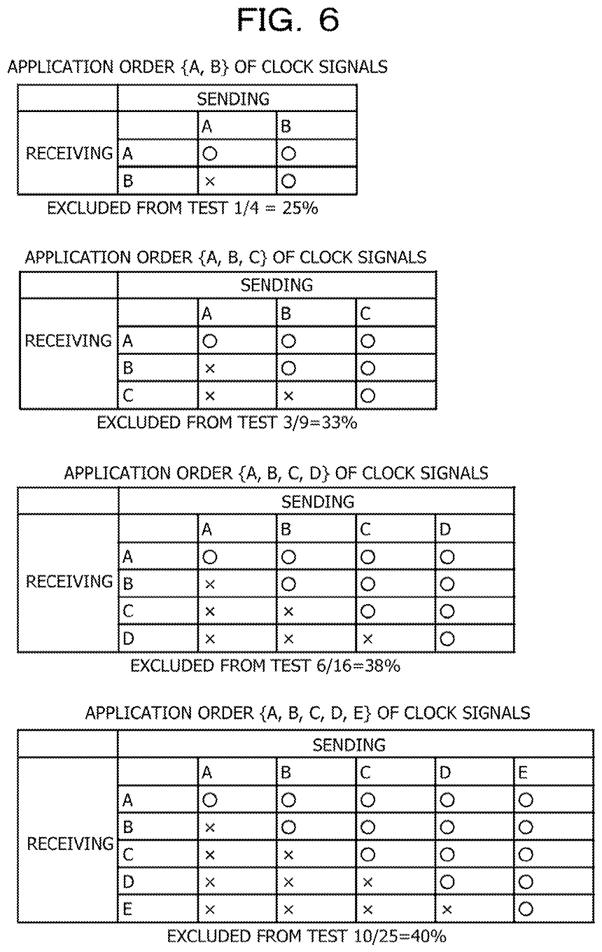

FIG. 6 is a diagram illustrating the number of clock signals and the combinations of crossings for which the additional test patterns are generated. “x” marks represent the combinations of crossings for which the additional test patterns are generated.

In a case where the clock signals are applied in order {A, B}, there is one combination of crossings (25%) for which an additional test pattern is generated (combination that generates a region excluded from the test) among all four combinations of clock signals to be applied to the clock domains on the sending side and the receiving side.

In a case where the clock signals are applied in order {A, B, C}, there are three combinations of crossings (33%) for which additional test patterns are generated among all nine combinations of clock signals to be applied to the clock domains on the sending side and the receiving side.

In a case where the clock signals are applied in order {A, B, C, D}, there are six combinations of crossings (38%) for which additional test patterns are generated among all 16 combinations of clock signals to be applied to the clock domains on the sending side and the receiving side.

In a case where the clock signals are applied in order {A, B, C, D, E}, there are 10 combinations of crossings (40%) for which additional test patterns are generated among all 25 combinations of clock signals to be applied to the clock domains on the sending side and the receiving side.

As the number of clock signals increases in this way, the number of combinations of crossings for which additional test patterns are generated also increases. For example, in the method (c), as the number of clock signals increases, the number of additional test patterns increases, resulting in the increase in the test costs.

Incidentally, in a high-performance LSI, a holding circuit (sequential circuit) such as a flip-flop (hereinafter referred to as non-scan FF) and a latch circuit, which have a smaller circuit area than a scan FF, is sometimes used in order to improve mounting density. Such a holding circuit is not included in a scan chain. In the method (c), in a case where such a holding circuit is used, a correct test pattern may not be generated.

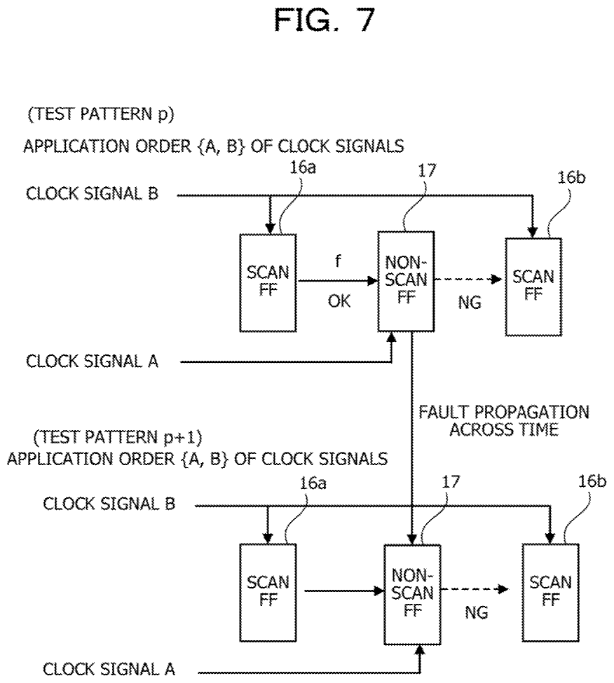

FIG. 7 is a diagram for describing a problem of the method (c) for a circuit including a non-scan FF. In FIG. 7, an example of a circuit in which a non-scan FF 17 operating with the clock signal A exists between scan FFs 16a and 16b operating with the clock signal B is indicated. Note that, in FIG. 7, illustration of a circuit region between the scan FF 16a and the non-scan FF 17 and a circuit region between the non-scan FF 17 and the scan FF 16b is omitted.

By a test pattern p with the application order {A, B} of the clock signals, a fault f assumed in the circuit region between the scan FF 16a and the non-scan FF 17 is propagated correctly, but the fault f is not propagated correctly between the non-scan FF 17 and the scan FF 16b.

Even when a test pattern p+1 with the application order {A, B} of the clock signals is added, data of the fault f captured in the non-scan FF 17 in the test pattern p may destroyed by application of the clock signal A. Thus, even when the clock signal B is next applied, the fault f may not be propagated to the scan FF 16b. For example, fault propagation across time may not be performed.

In this way, in the method (c), in a case where a holding circuit other than the scan FF is used to propagate test result data (fault fin the example described above), a disabled test pattern that is not actually capable of performing fault detection may have been generated.

Compared to this method, the test pattern generation method of the present embodiment may prevent generation of a disabled test pattern as described above. Hereinafter, the reason for this will be described more specifically.

FIG. 8 is a diagram illustrating an example of generation of a test pattern in the test pattern generation method of the present embodiment. In an LSI 13a illustrated in FIG. 8, elements same as those of the LSI 13 illustrated in FIG. 2 are denoted by the same reference signs. Note that illustration of the scan-in terminal SCIN, the scan-out terminal SCOUT, wiring coupling between the scan FF units, and the like illustrated in FIG. 2 is omitted. Furthermore, in FIG. 8, the combinations of clock signals applied to the clock domains on the sending side and the receiving side for each of the regions 15a to 15f are displayed as (A, A), (A, B), (B, A), and (B, B).

The LSI 13a illustrated in FIG. 8 includes a non-scan FF unit 18. The non-scan FF unit 18 includes one or a plurality of non-scan FFs. The non-scan FF unit 18 corresponds to the first holding circuit described above that sends an input value to the object circuit for the regions 15d and 15f, and also corresponds to the second holding circuit described above that receives output (response value from the object circuit) of the regions 15b and 15c.

When a test pattern for the LSI 13a as illustrated in FIG. 8 is generated, the processing unit 12 decides the application order of the clock signals as follows, for example. The application order is stored in the storage unit 11 as clock application order information as illustrated in FIG. 8, for example. The clock application order information is included in the test pattern information 11b described above. Note that, in the following example, a target is a fault in the region 15c, which is one of the crossing portions.

In an initial state of generation of the test pattern p, when the fault in the region 15c (response value from the object circuit of the region 15c) propagates to the non-scan FF unit 18, the processing unit 12 causes the non-scan FF unit 18 to capture the fault. Therefore, the processing unit 12 sets the clock signal A at the beginning of the application order by, for example, the ATPG function.

The processing unit 12 determines that fault propagation may be performed appropriately in a case where the application order of the clock signal A is at the beginning, because the combination of the clock signals to be applied to the clock domains on the sending side and the receiving side for the region 15c is (B, A), based on a result of detecting the clock domains. Thus, the processing unit 12 enables capture in the non-scan FF unit 18.

Next, since the fault is captured in the scan FF unit 14e when the fault propagates through the region 15f to the scan FF unit 14e, the processing unit 12 uses, for example, the ATPG function to set the clock signal B as the next application order of the clock signal A.

The processing unit 12 determines that fault propagation may not be performed appropriately in a case where the application order is the clock signals A and B, because the combination of the clock signals to be applied to the clock domains on the sending side and the receiving side for the region 15f is (A, B), based on the result of detecting the clock domains. Thus, the processing unit 12 disables capture of the fault (response value) in the scan FF unit 14e (for example, sets a state of a data input terminal to an uncontrolled state).

Since capture of the fault in the test pattern p has failed, the processing unit 12 deletes information in which the clock signal B is set to the second application order from the clock application order information. For example, by deleting the setting for applying the clock signal B in the test pattern p, the application order provisionally set by the ATPG function is changed.

Since fault propagation in the test pattern p has failed, the processing unit 12 starts generating the test pattern p+1 in order to enable the fault propagation.

In order to cause the scan FF unit 14e to capture the fault when the fault in the region 15c held by the non-scan FF unit 18 propagates to the scan FF unit 14e, the processing unit 12 sets the clock signal B at the beginning of the application order.

The processing unit 12 determines that fault propagation may be performed appropriately in a case where the application order of the clock signal B is at the beginning, because the combination of the clock signals to be applied to the clock domains on the sending side and the receiving side for the region 15c is (A, B), based on the result of detecting the clock domain. Thus, the processing unit 12 enables capture in the scan FF unit 14e.

As described above, in the test pattern generation method of the present embodiment, it is possible to recognize a path passing through the holding circuit other than the scan FF, such as the non-scan FF, which may not be recognized by the method (c), and thus it is possible to prevent generation of a disabled test pattern.

Note that a similar effect may be obtained by using a holding circuit such as a RAM instead of the non-scan FF unit 18.

Moreover, in the test pattern generation method of the present embodiment, by using the following method, the increase in the number of additional test patterns associated with the increase in the number of clock signals, as occurs in the method (c), may be suppressed.

FIG. 9 is a diagram illustrating an example of generation of a test pattern by a dynamic fault compression method.

In order to detect more faults in the same test pattern, the processing unit 12 may execute the following dynamic fault compression method. In FIG. 9, a state in which the test patterns p and p+1 illustrated in FIG. 8 are generated is set to an initial state.

For example, the processing unit 12 makes the following change so that a fault in the region 15a may be further detected in the test pattern p.

Since the fault is captured in the scan FF unit 14d when the fault in the region 15a propagates to the scan FF unit 14d, the processing unit 12 sets the clock signal B as the second application order by, for example, the ATPG function.

The processing unit 12 determines that fault propagation may also be performed appropriately with the application order of the clock signals A and B, because the combination of the clock signals to be applied to the clock domains on the sending side and the receiving side for the region 15a is (B, B), based on the result of detecting the clock domains. Thus, the processing unit 12 enables capture in the scan FF unit 14d.

In such a test pattern p, the regions other than the crossing portion represented by (A, B) are the test objects.

Next, the processing unit 12 makes the following change so that a fault in the region 15d may be further detected in the test pattern p+1.

Since the fault is captured in the scan FF unit 14f when the fault in the region 15d propagates to the scan FF unit 14f, the processing unit 12 sets the clock signal A as the second application order by, for example, the ATPG function.

The processing unit 12 determines that fault propagation may also be performed appropriately with the application order of the clock signals B and A, because the combination of the clock signals to be applied to the clock domains on the sending side and the receiving side for the region 15d is (A, A), based on the result of detecting the clock domains. Thus, the processing unit 12 enables capture in the scan FF unit 14f.

In such a test pattern p+1, the regions other than the crossing portion represented by (B, A) are the test objects.

As described above, in the test pattern generation method of the present embodiment, since the application order of the clock signals is variable like {A, B} and {B, A}, even when the number of clock signals increases, the number of additional test patterns may be suppressed compared with the method (c) in which the clock application order is fixed.

Comparison with (d) Clock Unify, Clock Supply/Stop Method

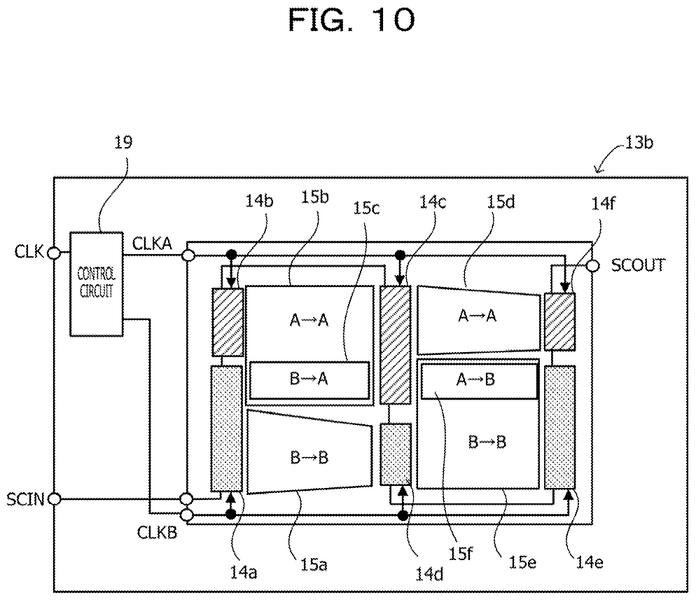

FIG. 10 is a diagram illustrating an example of a clock unify, clock supply/stop method. In FIG. 10, elements same as those of the LSI 13 illustrated in FIG. 2 are denoted by the same reference signs. A control circuit 19 is added to an LSI 13b illustrated in FIG. 10.

During capture operation, the control circuit 19 supplies a common clock signal to be applied to a clock terminal CLK to each clock domain via the clock terminals CLKA and CLKB.

This method assumes that the original plurality of clock signals is unified due to limitation of the number of terminals in a tester, so the number of clock signals supplied in the circuit is less than or equal to the original number of clock signals.

For example, after a test pattern is generated with a combination of clock signals that allows the circuit to operate normally (clock signals less than or equal to the original number of clock signals), an additional test pattern is generated with another combination of clock signals. Thus, similarly to the method (c), there is a problem of the increase in the test costs due to the addition of test patterns associated with the increase in the number of clock signals.

For example, in FIG. 10, a test is performed by supplying and controlling a clock signal via the clock terminals CLKA and CLKB to a circuit that operates normally without a problem of skew even when clock unification is performed. On the other hand, for a circuit that does not operate normally due to skew, a test pattern may be generated to stop the supply and control of the clock signal via one of the clock terminals CLKA and CLKB.

Compared to this method, the test pattern generation method of the present embodiment may apply the dynamic fault compression method as in FIG. 9 described above, and may suppress the increase in the number of additional test patterns.

Note that, in the description above, an example of generating a test pattern in a static test has been described, but the processing unit 12 may also generate a test pattern in a high-speed test. A method of generating a test pattern in a high-speed test will be described in the following second embodiment.

### Second Embodiment

Next, the second embodiment will be described.

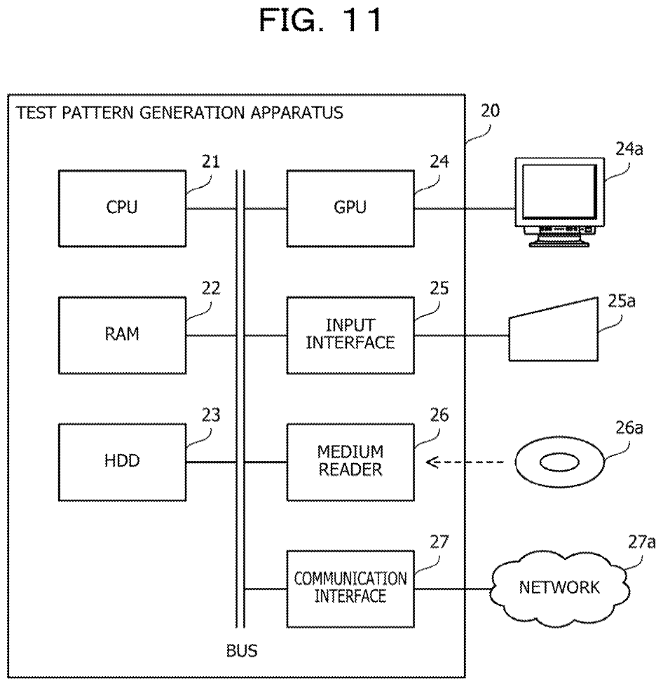

FIG. 11 is a block diagram illustrating a hardware example of a test pattern generation apparatus.

A test pattern generation apparatus 20 includes a CPU 21, a RAM 22, an HDD 23, a graphics processing unit (GPU) 24, an input interface 25, a medium reader 26, and a communication interface 27. The units described above are coupled to a bus.

The CPU 21 is a processor including an arithmetic circuit that executes a command of a program. The CPU 21 loads at least a part of a program and data stored in the HDD 23 into the RAM 22 to execute the program. Note that the CPU 21 may include a plurality of processor cores, the test pattern generation apparatus 20 may include a plurality of processors, and processing to be described below may be executed in parallel by using the plurality of processors or processor cores. Furthermore, a set of a plurality of processors (multiprocessor) may be called a “processor”.

The RAM 22 is a volatile semiconductor memory that temporarily stores a program executed by the CPU 21 and data used by the CPU 21 for arithmetic operations. Note that the test pattern generation apparatus 20 may include a memory of a type other than the RAM or may include a plurality of memories.

The HDD 23 is a non-volatile storage device that stores programs for software such as an operating system (OS), middleware, or application software, and data. For the program, for example, a test pattern generation program that causes the test pattern generation apparatus 20 to perform processing such as generation of a test pattern is provided. Note that the test pattern generation apparatus 20 may include other types of storage devices such as a flash memory and a solid state drive (SSD), or may include a plurality of non-volatile storage devices.

The GPU 24 outputs an image to a display 24a coupled to the test pattern generation apparatus 20 according to a command from the CPU 21. As the display 24a, a cathode ray tube (CRT) display, a liquid crystal display (LCD), a plasma display panel (PDP), an organic electro-luminescence (OEL) display, or the like may be used.

The input interface 25 acquires an input signal from an input device coupled to the test pattern generation apparatus 20, and outputs the input signal to the CPU 21. As the input device 25a, a pointing device such as a mouse, a touch panel, a touch pad, or a trackball, a keyboard, a remote controller, a button switch, or the like may be used. Furthermore, a plurality of types of input devices may be coupled to the test pattern generation apparatus

The medium reader 26 is a reading device that reads a program and data recorded on a recording medium 26a. As the recording medium 26a, for example, a magnetic disk, an optical disk, a magneto-optical disk (MO), a semiconductor memory, or the like may be used. Examples of the magnetic disk include a flexible disk (FD) and an HDD. Examples of the optical disk include a compact disc (CD) and a digital versatile disc (DVD).

The medium reader 26 copies, for example, a program or data read from the recording medium 26a to another recording medium such as the RAM 22, the HDD 23, or the like. The read program is executed by, for example, the CPU 21. Note that the recording medium 26a may be a portable recording medium, and may be used for distribution of a program or data. Furthermore, the recording medium 26a or the HDD 23 may be referred to as a computer-readable recording medium.

The communication interface 27 is an interface that is coupled to a network 27a, and communicates with another information processing device via the network 27a. The communication interface 27 may be a wired communication interface coupled by a cable to a communication device such as a switch, or may be a wireless communication interface coupled to a base station by a wireless link.

The test pattern generation apparatus 10 of the first embodiment illustrated in FIG. 1 may also be implemented with the hardware configuration as described above.

Next, functions and processing procedures of the test pattern generation apparatus 20 will be described.

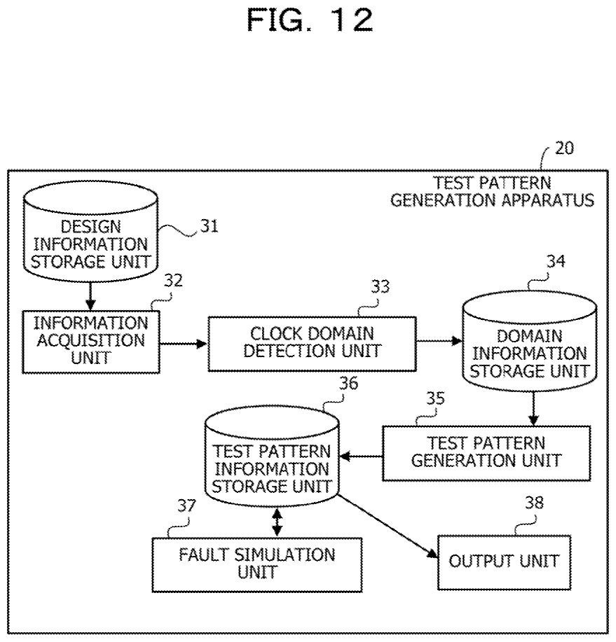

FIG. 12 is a block diagram illustrating a functional example of the test pattern generation apparatus.

The test pattern generation apparatus 20 includes a design information storage unit 31, an information acquisition unit 32, a clock domain detection unit 33, a domain information storage unit 34, a test pattern generation unit 35, a test pattern information storage unit 36, a fault simulation unit 37, and an output unit 38. The design information storage unit 31, the domain information storage unit 34, and the test pattern information storage unit 36 correspond to the storage unit 11 in FIG. 1, and may be implemented by using, for example, a storage region secured in the RAM 22 or the HDD 23. The information acquisition unit 32, the clock domain detection unit 33, the test pattern generation unit 35, the fault simulation unit 37, and the output unit 38 correspond to the processing unit 12 in FIG. 1, and may be implemented by using, for example, a program module executed by the CPU 21.

The design information storage unit 31 stores design information (circuit model) of an LSI. Note that the test pattern generation apparatus 20 may receive input from a user, create design information based on the input, and store the design information in the design information storage unit 31, or the test pattern generation apparatus 20 may acquire design information from another device, and store the design information in the design information storage unit 31. Note that a fault to be detected and various types of test conditions may be included in the design information.

The information acquisition unit 32 acquires (reads) the design information from the design information storage unit 31. Note that the information acquisition unit 32 may acquire the fault to be detected, the various types of test conditions, and the like from, for example, outside the test pattern generation apparatus 20.

The clock domain detection unit 33 detects, based on the design information, a plurality of clock domains each operating according to any one of a plurality of clock signals.

The domain information storage unit 34 stores information regarding the plurality of detected clock domains.

The test pattern generation unit 35 generates test patterns based on the information regarding the plurality of clock domains.

The test pattern information storage unit 36 stores information regarding the generated test patterns.

The fault simulation unit 37 uses the generated test patterns to perform fault simulation such as a static test and a high-speed test. Then, the fault simulation unit 37 evaluates a fault detection rate by the test patterns used, and stores a test pattern including an expected value in the test pattern information storage unit 36.

The output unit 38 outputs information regarding the test pattern including the expected value. The output unit 38 may output the information regarding the test pattern to the display 24a for display, or may store the information regarding the test pattern in a storage device such as the HDD 23 for storage. Furthermore, the output unit 38 may transmit the information regarding the test pattern to an external device.

(Test Pattern Generation in Static Test)

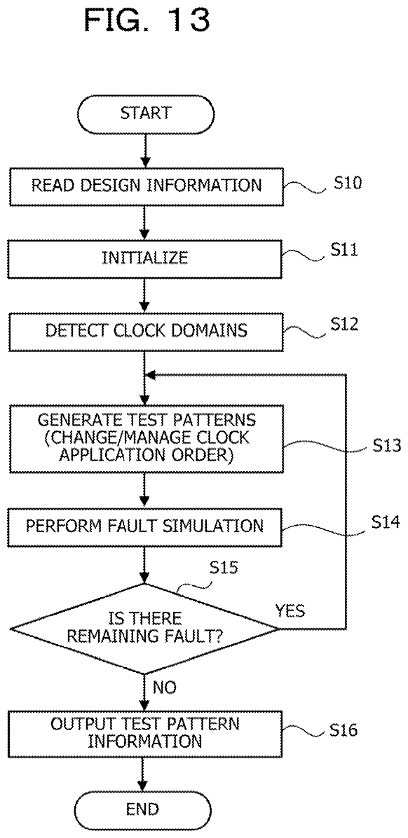

FIG. 13 is a flowchart illustrating an example of a procedure of generating a test pattern for a static test.

The information acquisition unit 32 reads design information from the design information storage unit 31 (Step S10). Thereafter, the clock domain detection unit 33, the test pattern generation unit 35, and the like are initialized (Step S11).

Next, detection of clock domains is performed by the clock domain detection unit 33 (Step S12).

The test pattern generation unit 35 generates test patterns including an input value to an object circuit and application order of a plurality of clock signals (Step S13). Here, the test pattern generation unit 35 changes/manages the application order based on which of the plurality of clock domains a first holding circuit that sends the input value to the object circuit or a response value from the object circuit to a circuit region of the LSI and a second holding circuit that receives the response value from the circuit region of the LSI are belong to any one of the plurality of clock domains.

The fault simulation unit 37 uses the generated test patterns to perform fault simulation (Step S14).

The test pattern generation unit 35 determines whether or not a fault to be detected remains (Step S15), and in a case where it is determined that a fault to be detected remains, performs the processing of Step S13 again.

In a case where it is determined that a fault to be detected does not remain, the output unit 38 outputs information regarding a test pattern including an expected value obtained by the fault simulation (Step S16). With this configuration, the test pattern generation processing ends.

(Procedure of Detecting Clock Domains)

FIG. 14 is a flowchart illustrating an example of a procedure of detecting clock domains.

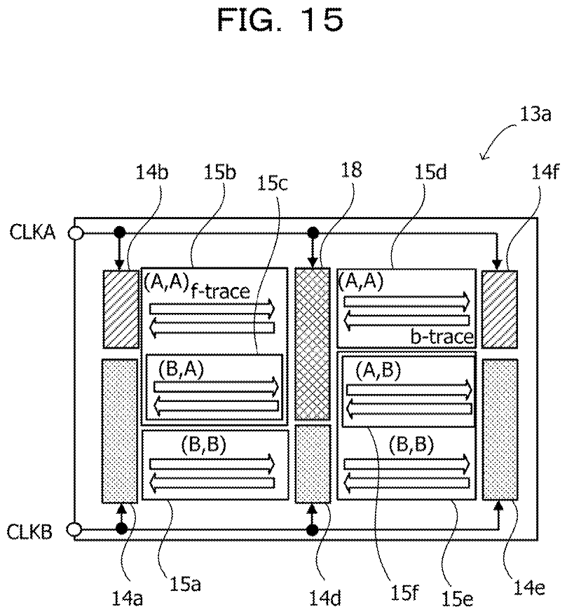

Furthermore, FIG. 15 is a diagram illustrating an example of detecting clock domains. FIG. 15 illustrates the example of detecting clock domains for the LSI 13a illustrated in FIG. 8.

The clock domain detection unit 33 selects one clock terminal, performs a forward trace from the same terminal, and extracts a reachable holding circuit (scan FF unit or non-scan FF unit) (Step S20). For example, the clock domain detection unit 33 selects a clock terminal CLKA in an LSI 13a as illustrated in FIG. 15, and extracts scan FF units 14b and 14f and a non-scan FF unit 18 reachable from the clock terminal CLKA by the forward trace.

Moreover, the clock domain detection unit 33 performs a forward trace from the reached holding circuit to the next holding circuit (Step S21). For example, the clock domain detection unit 33 performs the forward trace (“f-trace” in FIG. 15) from the scan FF unit 14b to the non-scan FF unit 18 and from the non-scan FF unit 18 to the scan FF unit 14f, as illustrated in FIG. 15.

Thereafter, the clock domain detection unit 33 performs a back trace from the reached holding circuit to the preceding holding circuit (Step S22). For example, the clock domain detection unit 33 performs the back trace (“b-trace” in FIG. 15) from the scan FF unit 14f to the non-scan FF unit 18 and from the non-scan FF unit 18 to the scan FF unit 14b, as illustrated in FIG. 15.

The clock domain detection unit 33 marks “send” in a region of the forward trace (Step S23), and marks “receive” in a region of the back trace (Step S24). For example, the mark “send” is given to, for example, a data input terminal of the FF included in the holding circuit where the forward trace starts, and the mark “receive” is given to, for example, a data input terminal of the FF included in the holding circuit where the back trace starts.

The “send” and the “receive” may be expressed by clock signal names applied to the clock domains on a sending side and a receiving side, respectively. For example, in FIG. 15, the clock signals applied to the clock domains on the sending side and the receiving side for the regions 15b and 15d are both the clock signal A, and thus referred to as (A, A). A result of such marking is stored in the domain information storage unit 34 as clock domain information.

Thereafter, the clock domain detection unit 33 determines whether or not all clock signals have been processed (Step S25). In a case where it is determined that all clock signals have not been processed, the clock domain detection unit 33 repeats the processing from Step S20. In a case where it is determined that all clock signals have been processed, the clock domain detection unit 33 ends the clock domain detection processing.

For example, in FIG. 15, a clock terminal CLKB is selected, and the processing from Steps S20 to S24 is repeated. With this configuration, (send, receive) for an optional region of the LSI 13a illustrated in FIG. 15 becomes any one of four types: (A, A), (B, B), (A, B), or (B, A).

(Procedure of Generating Test Pattern)

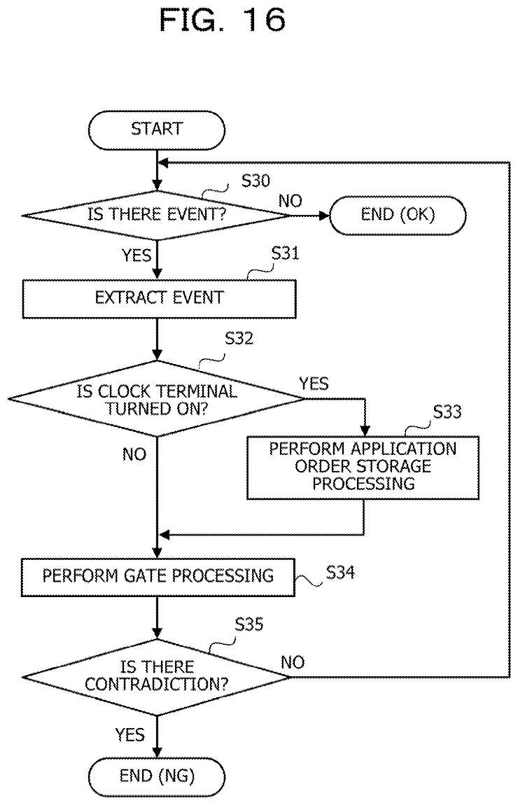

FIG. 16 is a flowchart illustrating an example of a procedure of generating a test pattern. In FIG. 16, an overall flow of implication processing in an ATPG function is illustrated.

The test pattern generation unit 35 determines whether or not there is an event in the implication processing (such as an event that turns on a certain clock terminal) (Step S30). The test pattern generation unit 35 performs processing of Step S31 in a case where it is determined that there is an event, and ends the test pattern generation processing in a case where it is determined that there is no event.

In the processing of Step S31, the test pattern generation unit 35 extracts the event of interest. Then, the test pattern generation unit 35 determines whether or not the event turns on the clock terminal (Step S32).

In a case where it is determined that the extracted event turns on the clock terminal, the test pattern generation unit 35 performs application order storage processing (Step S33). The application order storage processing is processing of storing application order as the clock application order information as illustrated in FIG. 8 described above. In a case where it is determined in the processing of Step S32 that the event turns on the clock terminal, a clock signal name (A or B in the example of FIG. 8) applied to the clock terminal is added to the application order.

After the processing of Step S33 or in a case where it is determined in the processing of Step S32 that the extracted event does not turn on the clock terminal, the test pattern generation unit 35 performs gate processing (Step S34). A procedure of the gate processing will be described later.

After the gate processing, the test pattern generation unit 35 determines whether or not there is a contradiction in a setting value of each holding circuit for detecting a fault, and in a case where it is determined that there is no contradiction, repeats the processing from Step S30. In a case where it is determined that there is a contradiction, it becomes NG and the test pattern generation processing ends.

(Procedure of Gate Processing)

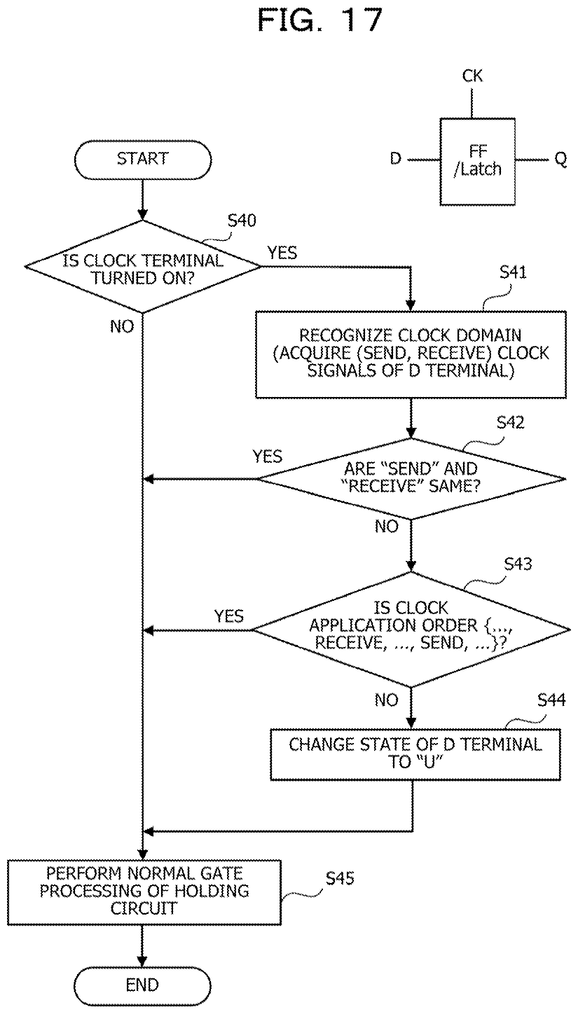

FIG. 17 is a flowchart illustrating an example of a procedure of the gate processing. Note that, in FIG. 17, examples of terminals (a CK terminal (clock terminal), a D terminal (data input terminal), a Q terminal (output terminal)) of a flip-flop (FF) or a latch circuit (Latch), which are examples of a holding circuit, are illustrated.

The test pattern generation unit 35 determines whether or not the event turns on the clock terminal (Step S40). In a case where it is determined that the event turns on the clock terminal, the test pattern generation unit 35 performs processing of Step S41. In a case where it is determined that the event does not turn on the clock terminal, the test pattern generation unit 35 performs processing of Step S45.

In the processing of Step S41, the test pattern generation unit 35 recognizes a clock domain. The test pattern generation unit 35 refers to clock domain information corresponding to the D terminal, and acquires “send” and “receive” clock signals to recognize the clock domain.

Then, the test pattern generation unit 35 determines whether or not the “send” and the “receive” are the same (Step S42). In a case where it is determined that the “send” and the “receive” are the same, the test pattern generation unit 35 performs the processing of Step S45, and in a case where it is determined that the “send” and the “receive” are not the same, the test pattern generation unit 35 performs processing of Step S43.

In the processing of Step S43, the test pattern generation unit 35 refers to the clock application order information, and determines whether or not the clock application order is { . . . , receive, . . . , send, . . . }. For example, from (send, receive) for regions 15a to 15f illustrated in FIG. 15 and the clock application order information, the test pattern generation unit 35 determines whether the clock application order is { . . . , receive, . . . , send, . . . } for each of the regions 15a to 15f. With this configuration, it is determined whether or not the application order is such that a fault may be appropriately transmitted when a clock signal applied to the clock terminal that is turned on is added to the application order.

For example, as illustrated in FIG. 8, for the region 15f for which (send, receive) is (A, B), in a case where the clock application order is {A, B}, it is determined that the clock application order is not { . . . , receive, . . . , send, . . . }.

Note that the reference { . . . , receive, . . . , send, . . . } indicates that clock signals different from the “send” or “receive” clock signal for the region of interest may be included in the portions of “ . . . ”.

In a case where it is determined that the clock application order is { . . . , receive, . . . , send, . . . }, the test pattern generation unit 35 performs the processing of Step S45, and in a case where it is determined that the clock application order is not { . . . , receive, . . . , send, . . . }, the test pattern generation unit 35 performs processing of Step S44.

In the processing of Step S44, the test pattern generation unit 35 sets a state of the D terminal of the holding circuit on the receiving side for the region where the clock application order is not { . . . , receive, . . . , send, . . . } to “U” (uncontrollable), and performs the processing of Step S45.

In the processing of Step S45, the test pattern generation unit 35 performs normal gate processing of the holding circuit. In the processing of Step S45, the test pattern generation unit 35 sets an input value to the object circuit included in the test pattern to the D terminal.

With this configuration, the gate processing ends.

By such gate processing, the clock application order is checked for each test pattern, and in a case where the clock application order is such that a fault may not be appropriately propagated, capture at the D terminal in the test pattern is disabled.

(Details of Clock Application Order Information)

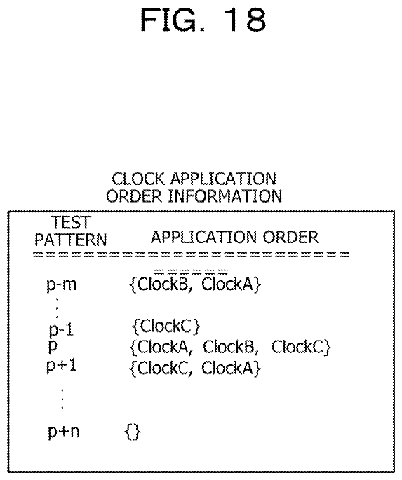

FIG. 18 is a diagram illustrating a detailed example of the clock application order information.

The clock application order information is array data with a size corresponding to the number of test patterns to be created. In each element of the array, a list of terminal names of clock terminals to which clock signals are applied (“ClockA”, “ClockB”, and the like in the example of FIG. 18) is stored. The terminal names are stored in order of application. Note that, as illustrated in FIG. 8, clock signal names (“A”, “B”, and the like) may be stored in each element of the array.

(Example of Updating Clock Application Order Information Using Decision Tree)

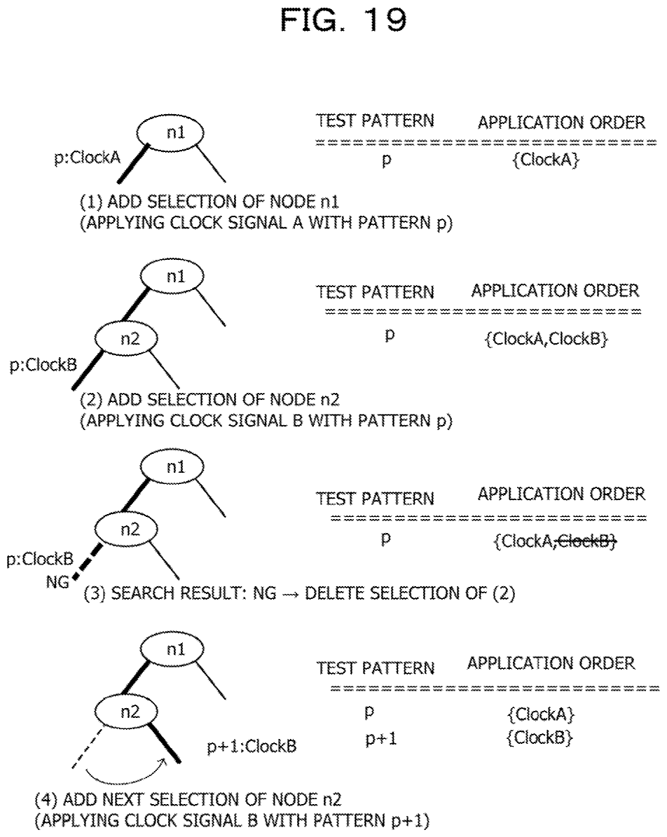

FIG. 19 is a diagram illustrating an example of updating the clock application order information using a decision tree. In FIG. 19, an example in which the application order similar to that in the example of generation of a test pattern illustrated in FIG. 8 is decided by using a decision tree.

First, selection of a node n1 is added to the clock application order information. The selection of the node n1 corresponds to applying a clock signal A (the clock signal applied to the clock terminal with the terminal name “ClockA”) in a pattern p.

Next, selection of a node n2 is added to the clock application order information. The selection of the node n2 corresponds to applying a clock signal B (the clock signal applied to the clock terminal with the terminal name “ClockB”) in the pattern p.

Thereafter, as illustrated in FIG. 8, since it is determined that fault propagation may not be performed appropriately (search result: NG) in the case of the application order of the clock signals A and B, the selection of the node n2 (applying the clock signal B) is deleted from the clock application order information.

Then, the next selection of the node n2 is added to the clock application order information. The next selection of the node n2 corresponds to applying the clock signal B in a pattern p+1.

(Generation of Test Pattern for High-Speed Test)

A high-speed test (also called an at-speed test) is a test that detects a delay fault in a path to be measured between holding circuits such as flip-flops and latch circuits. Hereinafter, a case will be described where a flip-flop or a latch circuit (referred to as FF/Latch) is used as an example of the holding circuit.

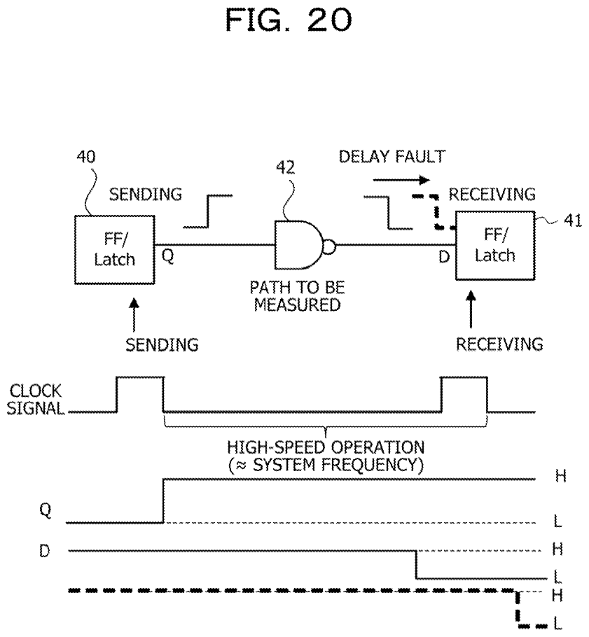

FIG. 20 is a diagram illustrating an outline of the high-speed test. In FIG. 20, an example of a high-speed test that detects a delay fault in a path to be measured (including a not AND (NAND) circuit 42) between FF/Latches 40 and 41 is illustrated.

In the high-speed test, the same (in-phase) pair of clock signals (with frequencies close to a system frequency actually used) is applied to both the FF/Latches 40 and 41 on the sending side and the receiving sides. In the example of FIG. 20, a signal output from a Q terminal of the FF/Latch 40, in which a logic level rises from a low (L) level to a high (H) level, reverses the logic level from the H level to the L level in the path to be measured. However, in a case where no change in the logic level is detected at a D terminal by a rising timing of the clock signal applied to the FF/Latch 41, it is determined that a delay fault has occurred.

In the example of the LSI 13a as illustrated in FIG. 8, regions subjected to the high-speed test are the regions 15b and 15d where the clock signal A is applied to the holding circuits on the sending side and the receiving side, and the regions 15a and 15e where the clock signal B is applied to the holding circuits on the sending side and the receiving side.

The methods (a) to (d) described above have the following problems when the high-speed test is performed.

Problem of (a) Single Clock Application Method

Although there is a difference that the clock signals are paired in the high-speed test, the test is performed on each clock signal as in the static test, so the test costs of the LSI increase as the number of clock signals increases.

Problem of (b) Multiple Clock Application Method (Time Expansion Method)

Although there is a difference that the clock signals are paired in the high-speed test, time expansion is performed on each clock signal as in the static test, so as the number of clock signals increases, the number of time frames to be expanded increases and the number of search spaces in which fault detection conditions are searched increases. With this configuration, the search problem to be handled becomes complex.

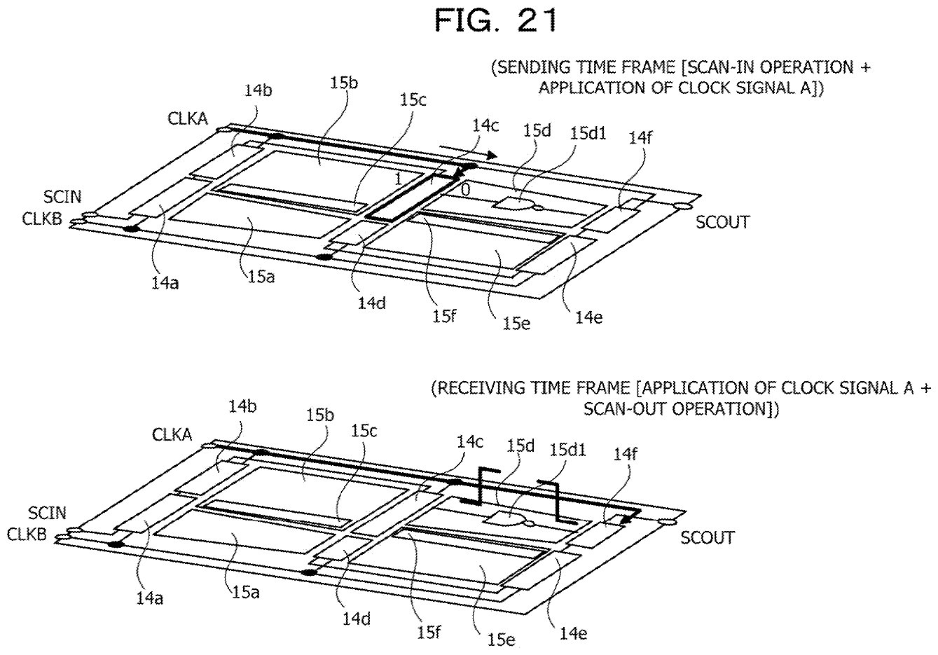

FIG. 21 is a diagram illustrating an example of time expansion during the high-speed test. In FIG. 21, the LSI 13 described above (see FIG. 2) is indicated, in which a sending time frame in which scan-in operation and application of the clock signal A are performed and a receiving time frame in which application of the clock signal A and scan-out operation are performed are indicated. The sending time frame represents a circuit state at the time data is sent to a circuit region of a test object, and the receiving time frame represents a circuit state at the time data is received from the circuit region of the test object.

For example, in a case where a delay fault in a path to be measured including a NAND circuit 15d1 in the region 15d is detected, a value=1 is set to an FF/Latch in the scan FF unit 14c in the sending time frame. Then, in the receiving time frame, data passing through the path to be measured is captured by an FF/Latch in the scan FF unit 14f.

In the method (b), since the circuit state is expressed by using the pair of time frames as described above for each clock signal, the search problem to be handled is more complex than that of the static test.

Problem of (c) Multiple Clock Application Method (Clock Application Order Fixing Method)

In the high-speed test, for example, a test object is a region where the clock signals applied to the clock domains on the sending side and the receiving side are the same (in-phase), such as “A→A” and “B→B” in the LSI 13 as illustrated in FIG. 5. Therefore, determination criteria related to the crossing portions such as “A→B” and “B→A” in the method (c) do not provide a solution to problems such as the increase in the test costs and deterioration in test quality in the high-speed test.

Problem of (d) Clock Unify, Clock Supply/Stop Method

The method (d) simplifies time expansion because it unifies a clock signal. However, even in the high-speed test, after a test pattern is generated with a combination of a plurality of clock signals, an additional test pattern with a combination of a plurality of different clock signals is needed, as in the static test. Thus, there is a problem of the increase in the test costs due to the addition of test patterns associated with the increase in the number of clock signals.

(Time Frame Reuse Method)

In the test pattern generation method of the present embodiment, the following method (referred to as a time frame reuse method) is used during the high-speed test.

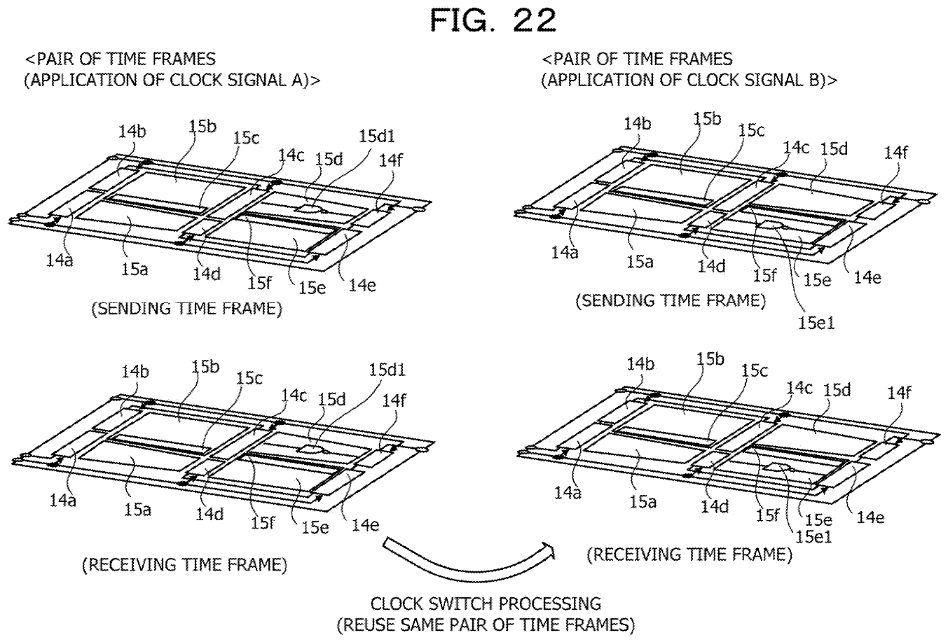

FIG. 22 is a diagram illustrating an example of the time frame reuse method. In FIG. 22, the LSI 13 described above (see FIG. 2) is indicated, in which a sending time frame in which scan-in operation and application of a clock signal are performed and a receiving time frame in which application of a clock signal and scan-out operation are performed are indicated.

In the example of FIG. 22, an example of a test pattern for the high-speed test in which it is assumed that the clock signal A is the first sending and receiving clock signal and the clock signal B is the next sending and receiving clock signal is indicated. Furthermore, in the example of FIG. 22, when the clock signal A is applied, the region 15d having the path to be measured including the NAND circuit 15d1 is subjected to the high-speed test. Furthermore, when the clock signal B is applied, the region 15e having a path to be measured including a NAND circuit 15e1 is subjected to the high-speed test.

In the test pattern generation method of the present embodiment, for example, the clock signal A is applied in each pair of the sending time frame and the receiving time frame, and thereafter, the clock signal B is applied in the same pair of time frames by clock switch processing. For example, unlike the method (b) described above, even when the number of clock signals increases, the same pair of time frames is reused, so the number of time frames does not increase. With this configuration, it is possible to prevent the search problem from becoming complex, and to reduce deterioration in the test quality due to search termination.

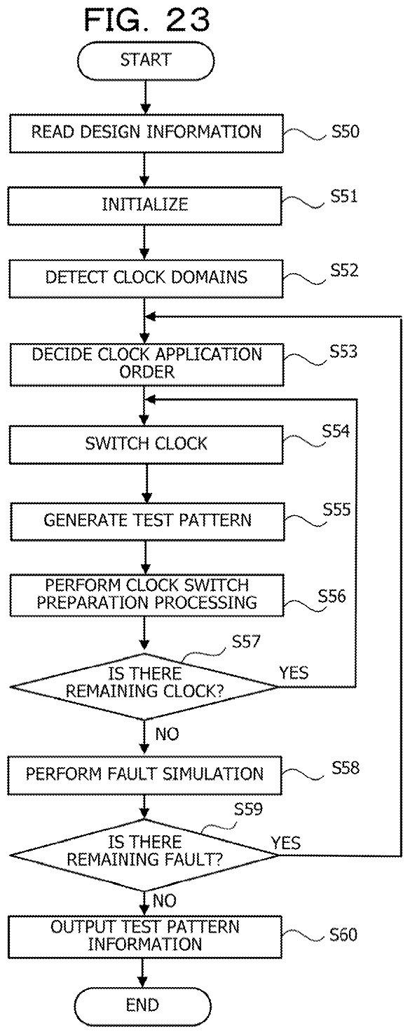

FIG. 23 is a flowchart illustrating an example of a procedure of generating a test pattern for the high-speed test. Note that the procedure in FIG. 23 includes the procedure in the static test illustrated in FIG. 13. The description of the processing similar to the processing in the static test is omitted.

Processing of Steps S50 to S52 is the same as the processing of Steps S10 to S12 illustrated in FIG. 13.

After the processing of Step S52, the test pattern generation unit 35 decides application order of clock signals in the high-speed test (Step S53). For example, the test pattern generation unit 35 decides the application order so that clock signals to be applied to the clock domains on the sending side and the receiving side for a region with the large number of faults are prioritized based on information regarding a plurality of clock domains and fault information related to a delay fault.

Next, the test pattern generation unit 35 performs the clock switch processing (Step S54). In the processing of Step S54, a circuit state when the clock signal to be applied is switched between a sending time frame and a receiving time frame is set. An example of the circuit state and an example of a procedure of the clock switch processing will be described later.

After the processing of Step S54, the test pattern generation unit 35 generates a test pattern for the high-speed test in the set circuit state (Step S55)

After the processing of Step S55, the test pattern generation unit 35 performs clock switch preparation processing (Step S56). In the processing of Step S56, a circuit state for initialization for a clock signal to be selected next is acquired. An example of a procedure of the clock switch preparation processing will be described later.

After the processing of Step S56, the test pattern generation unit 35 determines whether or not there is a clock signal (remaining clock) that has not been switched in the clock switch processing of Step S54 (Step S57). In a case where it is determined that there is a remaining clock, the processing from Step S54 is repeated, and in a case where it is determined that there is no remaining clock, processing of Step S58 is performed.

Processing of Steps S58 to S60 is the same as the processing of Steps S14 to S16 illustrated in FIG. 13. Note that, in a case where it is determined in the processing of Step S59 that there is a remaining fault, the processing from Step S53 is repeated.

(Procedure of Clock Switch Processing)

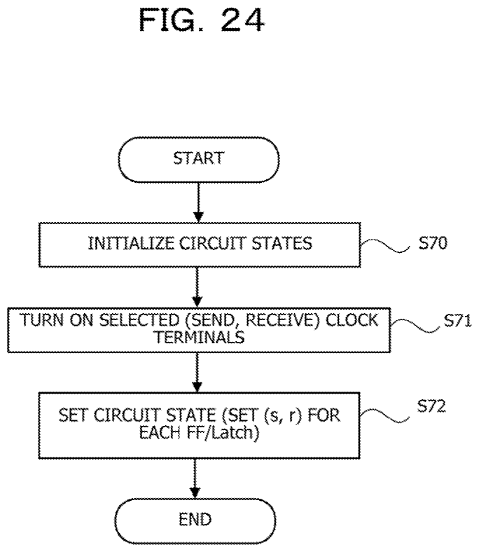

FIG. 24 is a flowchart illustrating an example of the procedure of the clock switch processing.

The test pattern generation unit 35 initializes the circuit states of the sending time frame and the receiving time frame (Step S70).

Based on the application order decided in the processing of Step S53 described above, the test pattern generation unit 35 selects and turns on a clock terminal to which any one of the clock signals is applied in the sending time frame and the receiving time frame (Step S71).

The test pattern generation unit 35 sets a circuit state for performing the high-speed test by using the clock signal applied to the selected clock terminal described above (Step S72). In the processing of Step S72, the test pattern generation unit 35 acquires a circuit state that may be set at the time of the current application of the clock signal, among the circuit states set by the previous application of the clock signal, and sets the circuit state. The circuit state is, for example, values of the send “s” and the receive “r” of the holding circuit (such as the FF/Latch included in the FF unit described above).

Thus, the clock switch processing ends.

(Procedure of Clock Switch Preparation Processing)

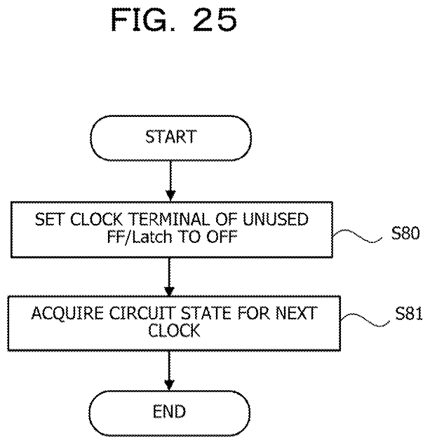

FIG. 25 is a flowchart illustrating an example of the procedure of the clock switch preparation processing.

The test pattern generation unit 35 sets a clock terminal of an unused FF/Latch to OFF (Step S80), and acquires a circuit state to be used when a clock signal in the next application order is applied (Step S81).

Thus, the clock switch preparation processing ends.

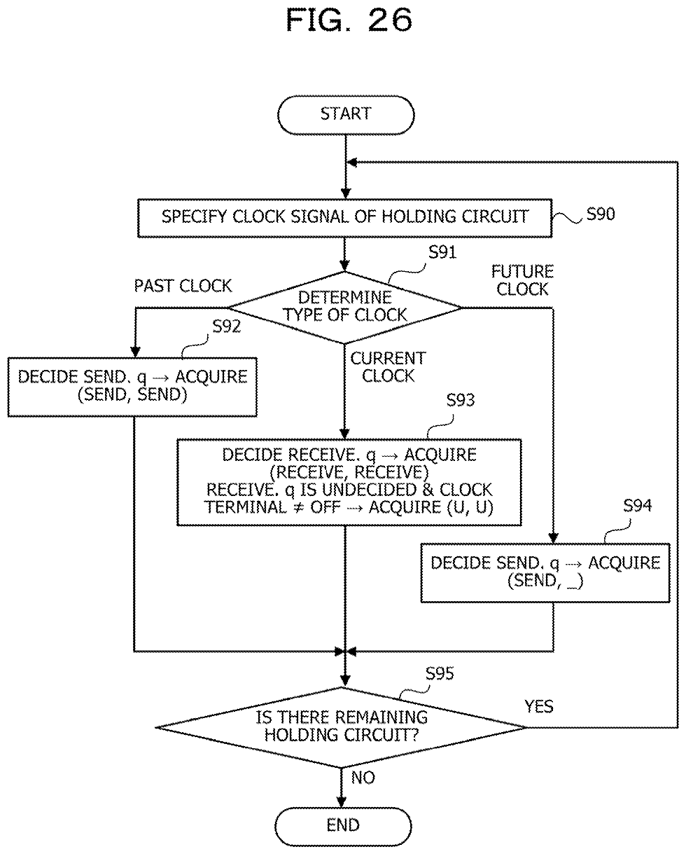

FIG. 26 is a flowchart illustrating an example of a procedure of the circuit state acquisition processing. In FIG. 26, an example of the procedure of the processing of Step S81 described above is indicated.

The test pattern generation unit 35 performs the following processing for each holding circuit (FF/Latch or the like).

First, the test pattern generation unit 35 specifies a clock signal applied to the holding circuit based on clock domain information (Step S90).

Then, the test pattern generation unit 35 determines a type of the clock signal (Step S91). In the processing of Step S91, it is determined whether the specified clock signal is a clock signal before switching in the processing of Step S54, a clock signal after switching, or a clock signal scheduled to be switched in the future. Hereinafter, the clock signal before switching is referred to as a past clock, the clock signal after switching is referred to as a current clock, and a clock signal scheduled to be switched in the future is referred to as a future clock.

In a case where it is determined that the specified clock signal is the past clock, the test pattern generation unit 35 performs processing of Step S92. In the processing of Step S92, when an output value of the holding circuit in the sending time frame (send. q) is decided, the test pattern generation unit 35 acquires the send. q as a circuit state (send, send) used when the next clock signal is applied. When q, which is the output value of the holding circuit in the sending time frame, is decided, the state of the holding circuit is not updated, and thus, in this way, q is acquired as the circuit state to be set with the next clock signal. The (send, send) indicates the circuit state in which the same value as the send. q is set as the output value of the holding circuit in both the sending time frame and the receiving time frame.

In a case where it is determined that the specified clock signal is the current clock, the test pattern generation unit 35 performs processing of Step S93. In the processing of Step S93, when an output value of the holding circuit in the receiving time frame (receive. q) is decided, the test pattern generation unit 35 acquires the receive. q as a circuit state (receive, receive) used when the next clock signal is applied. The (receive, receive) indicates the circuit state in which the same value as the receive. q is set as the output value of the holding circuit in both the sending time frame and the receiving time frame. Furthermore, when the output value of the holding circuit in the receiving time frame (receive. q) is undecided and the clock terminal≠OFF, the test pattern generation unit 35 acquires a circuit state used when the next clock signal is applied as (U, U). The (U, U) indicates that the circuit state set as the output value of the holding circuit in both the sending time frame and the receiving time frame is uncontrollable.

In a case where it is determined that the specified clock signal is the future clock, when an output value of the holding circuit in the sending time frame (send. q) is decided, the test pattern generation unit 35 acquires a circuit state used when the next clock signal is applied as (send, _) (Step S94). The (send, _) indicates the circuit state in which the same value as the send. q is set as the output value of the holding circuit in the sending time frame.

After the processing of Steps S92 to S94, the test pattern generation unit 35 determines whether or not there is a remaining holding circuit (Step S95).

In a case where it is determined that there is a remaining holding circuit, the test pattern generation unit 35 repeats the processing from Step S90, and in a case where it is determined that there is no remaining holding circuit, the test pattern generation unit 35 ends the circuit state acquisition processing.

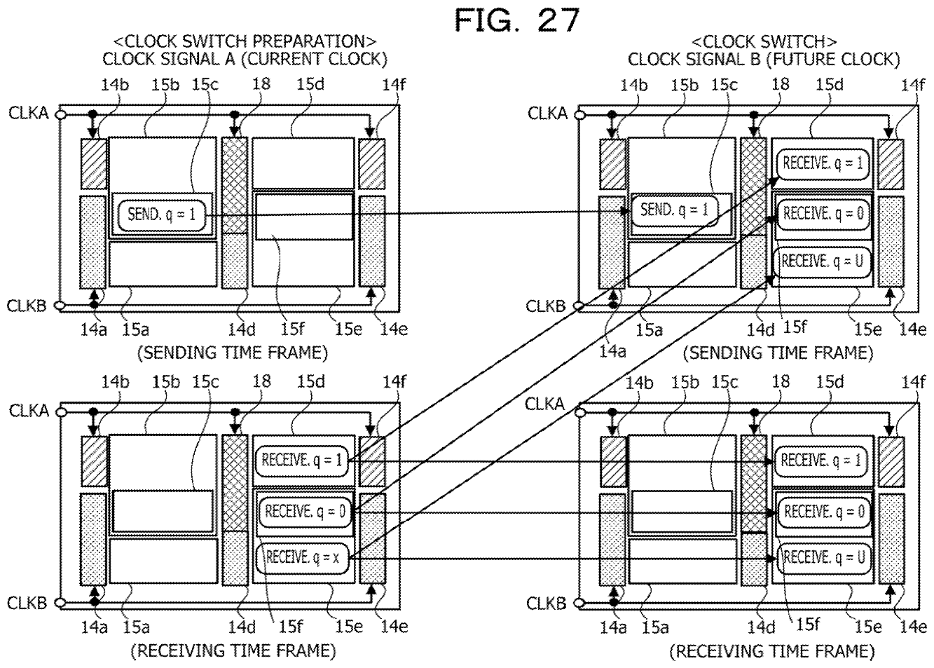

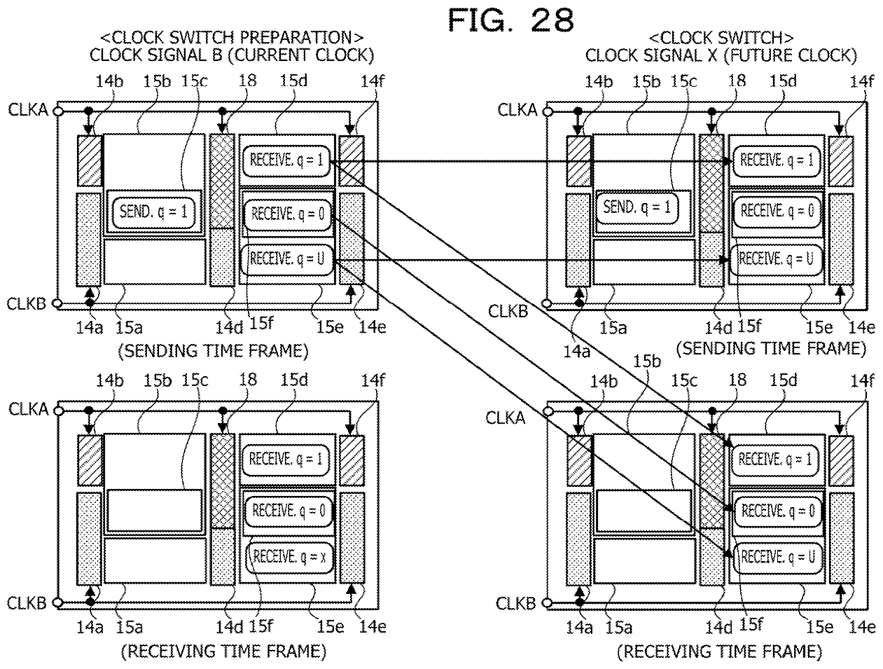

FIGS. 27 and 28 are diagrams illustrating an example of circuit state acquisition and setting processing. Note that, in FIGS. 27 and 28, an example of circuit state acquisition and setting processing for an LSI that is almost similar to the LSI 13a illustrated in FIG. 8. Note that, for convenience of description, it is assumed that the scan FF unit 14d operates with the clock signal A instead of the clock signal B.

In FIG. 27, an example of a case where a test pattern is generated in which application order of {a clock signal in the sending time frame, a clock signal in the receiving time frame} is set to {A, A} and {B, B} is indicated. On a left side of FIG. 27, a state of acquisition of the circuit state in the clock switch preparation processing of Step S56 in FIG. 23 described above after generation of the test pattern by the clock signal A is indicated. Furthermore, on a right side of FIG. 27, a state of setting of the circuit state in the clock switch processing of Step S54 in FIG. 23 described above before generation of the test pattern by the clock signal B is indicated.

As indicated on the left side of FIG. 27, in the receiving time frame, the circuit state of the non-scan FF unit 18 operated by the clock signal A as the current clock is decided to be q=1 or q=0. Such a circuit state is not updated by the next application of the clock signal B. Therefore, such a circuit state is acquired and set as an initial value in the sending time frame and the receiving time frame when the test pattern of the clock signal B is generated, as indicated on the right side of FIG. 27. Such acquisition processing corresponds to the processing of acquiring the circuit state in a case where the receive. q is decided in the processing of Step S93 in FIG. 26.

On the other hand, as indicated on the left side of FIG. 27, the circuit state of the scan FF unit 14d operated by the clock signal A is not decided as q=x (undecided) in the receiving time frame. In such a circuit state, it is unknown whether a value of q, which is an output value of the scan FF unit 14d, becomes 0 or 1 by the next application of the clock signal B. Therefore, such a circuit state is acquired and set as receive. q=U (uncontrollable) in the sending time frame and the receiving time frame when the test pattern of the clock signal B is generated, as indicated on the right side of FIG. 27. Such acquisition processing corresponds to the processing of acquiring the circuit state in a case where the receive. q is undecided and the clock terminal≠OFF in the processing of Step S93 in FIG. 26.

Moreover, as indicated on the left side of FIG. 27, in the sending time frame, the circuit state of the scan FF unit 14a operated by the clock signal B as the future clock is decided to be q=1. Such a circuit state is due to an input value (scan-in value) before being affected by the clock signal B that is to be applied next. Therefore, such a circuit state is acquired and set as an initial value in the sending time frame when the test pattern of the clock signal B is generated, as indicated on the right side of FIG. 27. Such acquisition processing corresponds to the processing of Step S94 in FIG. 26.

In FIG. 28, an example of a case where a test pattern is generated to which a clock signal X is applied in the sending time frame and the receiving time frame after {A, A} and {B, B} is indicated. Note that, in the example of FIG. 28, since only the clock signals A and B are applied, the clock signal X is not actually applied, but such a clock signal X is assumed for convenience of description.

On a left side of FIG. 28, a state of acquisition of the circuit state in the clock switch preparation processing of Step S56 in FIG. 23 described above after generation of the test pattern by the clock signal B is indicated. Furthermore, on a right side of FIG. 28, a state of setting of the circuit state in the clock switch processing of Step S54 in FIG. 23 described above before generation of the test pattern by the clock signal X is indicated.

As indicated on the left side of FIG. 28, in the sending time frame, the circuit states of the non-scan FF unit 18 and the scan FF unit 14d operated by the clock signal A as the past clock are decided to be q=1, q=0, and q=U. Such circuit states are not updated by subsequent application of the clock signal X. Therefore, such circuit states are acquired and set as initial values in the sending time frame and the receiving time frame when the test pattern of the clock signal X is generated, as indicated on the right side of FIG. 28. Such acquisition processing corresponds to the processing of Step S92 in FIG. 26.

As described above, according to the test pattern generation apparatus 20 of the second embodiment, as in the test pattern generation apparatus 10 of the first embodiment, even when the number of clock signals increases due to further multi-functionalization, the test costs in the static test may be reduced. Furthermore, it is possible to reduce deterioration in the test quality seen in the method (b).

Moreover, according to the test pattern generation apparatus 20 of the second embodiment, the test pattern is generated by using the sending time frame representing the circuit state of the LSI at the time of sending data to the circuit region of the test object and the receiving time frame representing the circuit state of the LSI at the time of receiving data from the circuit region. At this time, the clock signal to be used in the predetermined order is switched, and based on the result of the operation by the clock signal before switching, the circuit state of the sending time frame or the receiving time frame when the clock signal after switching is applied is set (see FIGS. 27 and 28). For example, the pair of time frames is reused even when the clock signal changes. By using such a time frame reuse method, it is possible to obtain the effect of reducing the test costs in the high-speed test and the effect of reducing deterioration in the test quality.

Note that the order of the processing indicated in each flowchart described above is an example, and the order of the processing may be appropriately changed.

Note that, as described above, the processing contents described above may be implemented by causing the test pattern generation apparatuses 10 and 20 to execute the program (test pattern generation program).

The program may be recorded in a computer-readable recording medium (for example, the recording medium 26a). As the recording medium, for example, a magnetic disk, an optical disk, a magneto-optical disk, a semiconductor memory, or the like may be used. The magnetic disk includes an FD and an HDD. The optical disk includes a CD, a CD-recordable (R)/rewritable (RW), a DVD, and a DVD-R/RW. The program may be recorded in a portable recording medium and distributed. In that case, the program may be copied from the portable recording medium to another recording medium (for example, the HDD 23) and then executed.

In the above, one aspect of the test pattern generation program, the test pattern generation apparatus, and the test pattern generation method of the embodiments has been described based on the embodiments. However, these are merely examples, and are not limited to the description above.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium storing a test pattern generation program for causing a computer to execute processing comprising:
detecting, based on design information of a semiconductor integrated circuit, a plurality of clock domains each of which operates according to any one of a plurality of clock signals;
changing application order of the plurality of clock signals when a test pattern that includes the application order and a first input value to a first object circuit is generated, based on which of the plurality of clock domains a first holding circuit that sends the first input value or a first response value from the first object circuit to the first circuit region and a second holding circuit that receives the first response value from the first circuit region, belong to; and
outputting information regarding the test pattern.

2. The non-transitory computer-readable recording medium according to claim 1, for causing the computer to execute the processing further comprising
changing, in a case where the application order is set such that a second clock signal to be applied to the second holding circuit is applied next to a first clock signal to be applied to the first holding circuit, the application order by deleting setting to apply of the second clock signal in the test pattern.

3. The non-transitory computer-readable recording medium according to claim 2, for causing the computer to execute the processing further comprising:
disabling capture of the first response value by the second holding circuit in a case where the setting to apply the second clock signal is deleted; and
changing, in a case where a third holding circuit that sends a second input value to a second object circuit included in the test pattern to a second circuit region different from the first circuit region and a fourth holding circuit that receives a second response value from the second object circuit of the second circuit region, belong to the same clock domain, the application order such that a third clock signal to be applied to the third holding circuit and the fourth holding circuit is applied next to the first clock signal.

4. The non-transitory computer-readable recording medium according to claim 1, wherein one of the first holding circuit and the second holding circuit is one of a plurality of serially coupled scan flip-flops, and another one of the first holding circuit and the second holding circuit is a holding circuit that is not included in the plurality of scan flip-flops.

5. The non-transitory computer-readable recording medium according to claim 1, for causing the computer to execute the processing further comprising,
in a case where the test pattern for a high-speed test of the semiconductor integrated circuit is generated by using a first time frame that represents a first circuit state of the semiconductor integrated circuit at a time of sending of data to a circuit region of a test object, and a second time frame that represents a second circuit state of the semiconductor integrated circuit at a time of reception of data from the circuit region,
switching a clock signal to be used among the plurality of clock signals in predetermined order, and setting, based on a result of operation of the semiconductor integrated circuit by a clock signal before the switching, the first circuit state or the second circuit state when a clock signal after the switching is applied.

6. The non-transitory computer-readable recording medium according to claim 5, wherein the first circuit state and the second circuit state are output values of the first holding circuit or the second holding circuit.

7. A test pattern generation apparatus comprising:
a memory; and
a processor coupled to the memory and configured to:
detect, based on design information of a semiconductor integrated circuit, a plurality of clock domains each of which operates according to any one of a plurality of clock signals;
change application order of the plurality of clock signals when a test pattern that includes the application order and a first input value to a first object circuit is generated, based on which of the plurality of clock domains a first holding circuit that sends the first input value or a first response value from the first object circuit to the first circuit region and a second holding circuit that receives the first response value from the first circuit region are belong to; and
output information regarding the test pattern.

8. A test pattern generation method comprising:
detecting, based on design information of a semiconductor integrated circuit, a plurality of clock domains each of which operates according to any one of a plurality of clock signals;
changing application order of the plurality of clock signals when a test pattern that includes the application order and a first input value to a first object circuit is generated, based on which of the plurality of clock domains a first holding circuit that sends the first input value or a first response value from the first object circuit to the first circuit region and a second holding circuit that receives the first response value from to the first circuit region are belong to; and
outputting information regarding the test pattern.
